(19) United States
(12) Patent Application Publication
(10) Pub. No.: US 2024/0425656 A1
(43) Pub. Date: Dec. 26, 2024

(54) NANOPARTICLE COMPOSITION, NANOPARTICLE-CONTAINING FILM, LIGHT-EMITTING ELEMENT, WAVELENGTH CONVERSION MEMBER, DISPLAY DEVICE, AND METHOD FOR PRODUCING NANOPARTICLE-CONTAINING FILM

(71) Applicant: SHARP KABUSHIKI KAISHA, Sakai City, Osaka (JP)

(72) Inventors: HIROFUMI YOSHIKAWA, Sakai City Osaka (JP); YASUSHI ASAOKA, Sakai City, Osaka (JP)

(21) Appl. No.: 18/577,367

(22) PCT Filed: Sep. 6, 2021
(86) PCT No.: PCT/JP2021/032687

§ 371 Date: Jan. 8, 2024

(51) Int. Cl. C08J 5/18; B82Y 30/00; C08G 63/66; C08K 3/04; C08K 5/5377; H01L 33/50

(52) U.S. Cl. CPC C08J 5/18; B82Y 30/00; C08G 63/66; C08K 3/042; C08K 5/5377; H01L 33/502; C08J 2331/02

(57) ABSTRACT

A nanoparticle composition includes: out of nanoparticles and ligands, at least the nanoparticles; and a curable monomer. At least the nanoparticles or the ligands contained in the nanoparticle composition contain aromatic rings. The curable monomer contains an aromatic monomer.

### TECHNICAL FIELD

The present disclosure relates to a nanoparticle composition, a nanoparticle-containing film, a light-emitting element, a wavelength conversion member, a display device, and a method for producing a nanoparticle-containing film.

### BACKGROUND ART

Patent Document 1 discloses a display device having a multilayer structure including a light-emitting layer. The light-emitting layer contains a quantum dot polymer and serves as a nanoparticle-containing film. In Patent Document 1, a quantum dot composition containing quantum dots, a photopolymerizable compound, a carboxylic acid linear polymer (a binder), a photo initiator, and an organic solvent is applied. Then, the quantum dot composition is exposed to light, and crosslinked and polymerized. As a result, the light-emitting layer is formed to contain the quantum dot polymer complex dispersed in a polymer matrix.

Furthermore, Patent Document 2 discloses an organic electroluminescence element having, as a nanoparticle-containing film, a metal oxide nanoparticle-containing film in which metal oxide nanoparticles are dispersed in an actinic radiation curable resin. In Patent Document 2, a curable monomer, a metal oxide nanoparticle-dispersed solution, and a polymerization initiator are mixed together and dissolved. After that, the obtained mixed solution (a metal oxide nanoparticle composition) is applied and irradiated with ultraviolet rays serving as actinic rays. As a result, a film is formed to contain the metal oxide nanoparticles dispersed in the actinic radiation curable resin.

### CITATION LIST

### Patent Literature

[Patent Document 1] Japanese Unexamined Patent Application Publication No. 2019-109515

[Patent Document 2] Japanese Unexamined Patent Application Publication No. 2015-099804

### Non-Patent Literature

[Non-Patent Document 1] Improved electroluminescence of quantum dot light-emitting diodes enabled by a partial ligand exchange with benzenethiol, Kim et al., Nanotechnology 27 (2016) 245203

### SUMMARY

### Technical Problems

However, as described in Patent Documents 1 and 2, a coating liquid (a nanoparticle composition) used for forming a known nanoparticle-containing film contains a solvent. Hence, at a step of forming the nanoparticle-containing film, a coffee ring effect is observed and impurities are mixed into the nanoparticle-containing film when the solvent contained in the coating film is removed by, for example, evaporation. Consequently, the resulting element or device including the nanoparticle-containing film suffers deterioration in characteristics.

An aspect of the present disclosure is conceived in view of the above problems. The aspect of the present disclosure is set out to provide a nanoparticle composition that can form a nanoparticle-containing film in which nanoparticles are dispersed in a cured resin without a solvent, and reduce a coffee ring effect observed when a solvent is evaporated. Furthermore, the aspect of the present disclosure is set out to provide the nanoparticle-containing film, a light-emitting element, a wavelength conversion member, a display device, and a method for producing the nanoparticle-containing film, all of which use the nanoparticle composition.

### Solution to Problems

In order to solve the above problems, a nanoparticle composition according to an aspect of the present disclosure includes: out of nanoparticles and ligands, at least the nanoparticles; and a curable monomer. At least the nanoparticles or the ligands contained in the nanoparticle composition contain aromatic rings, and the curable monomer contains an aromatic monomer.

In order to solve the above problems, a nanoparticle-containing film according to an aspect of the present disclosure includes: out of nanoparticles and ligands, the nanoparticles; and a cured resin. At least the nanoparticles or the ligands contained in the nanoparticle-containing film contain aromatic rings, and the cured resin contains an aromatic polymer.

In order to solve the above problems, a light-emitting element according to an aspect of the present disclosure includes the nanoparticle-containing film according to an aspect of the present disclosure.

In order to solve the above problems, a display device according to an aspect of the present disclosure includes the light-emitting element according to an aspect of the present disclosure.

In order to solve the above problems, a wavelength conversion member according to an aspect of the present disclosure includes, as a wavelength conversion layer, the nanoparticle-containing film according to an aspect of the present disclosure.

In order to solve the above problems, a display device according to an aspect of the present disclosure includes the wavelength conversion member according to an aspect of the present disclosure.

In order to solve the above problems, a method for producing a nanoparticle-containing film according to an aspect of the present disclosure includes: an applying step of applying a nanoparticle composition, the nanoparticle composition containing, out of nanoparticles and ligands, the nanoparticles and a curable monomer containing an aromatic monomer; and a curable step of curing at least a portion of the curable monomer of the nanoparticle composition applied at the applying step. At least the nanoparticles or the ligands contained in the nanoparticle composition contain aromatic rings.

### Advantageous Effects of Disclosure

An aspect of the present disclosure can provide a nanoparticle composition that can form a nanoparticle-containing film in which nanoparticles are dispersed in a cured resin without a solvent, and reduce a coffee ring effect observed when a solvent is evaporated. Furthermore, the aspect of the present disclosure can provide the nanoparticle-containing film, a light-emitting element, a wavelength conversion member, and a display device, all of which use the nanoparticle composition. Furthermore, an aspect of the present disclosure can provide a method for successfully producing a nanoparticle-containing film in which nanoparticles are dispersed in a cured resin without a solvent, so that the nanoparticle-containing film can reduce a coffee ring effect observed when a solvent is evaporated.

### BRIEF DESCRIPTION OF DRAWINGS

FIG. 1 is a cross-sectional view schematically illustrating an example of a nanoparticle composition according to a first embodiment.

FIG. 2 is a cross-sectional view illustrating a schematic configuration of a light-emitting element according to the first embodiment.

FIG. 3 is a flowchart showing an example of a method for producing the light-emitting element according to the first embodiment.

FIG. 4 is a flowchart showing an example of a quantum dot composition producing step shown in FIG. 3.

FIG. 5 is a diagram schematically illustrating an example of the quantum dot composition producing step shown in FIG. 3.

FIG. 6 schematically shows an example of a mixing step shown in FIG. 4.

FIG. 7 is a flowchart showing an example of a light-emitting layer forming step shown in FIG. 3.

FIG. 8 is a diagram schematically illustrating an example of the light-emitting layer forming step shown in FIG. 3.

FIG. 9 is a cross-sectional view illustrating an example of a schematic configuration of a main feature of a display device according to the first embodiment.

FIG. 10 is a schematic view illustrating an example of a schematic configuration of a main feature of the display device according to the first embodiment.

FIG. 11 is a cross-sectional view illustrating a schematic configuration of a light-emitting element according to a second embodiment.

FIG. 12 is a flowchart showing an example of a method for producing the light-emitting element according to the second embodiment.

FIG. 13 is a flowchart showing an example of a second carrier transport layer forming step shown in FIG. 12.

FIG. 14 is a cross-sectional view schematically illustrating an example of a quantum dot composition according to a third embodiment.

FIG. 15 is a cross-sectional view illustrating a schematic configuration of a light-emitting element according to the third embodiment.

### DESCRIPTION OF EMBODIMENTS

### First Embodiment

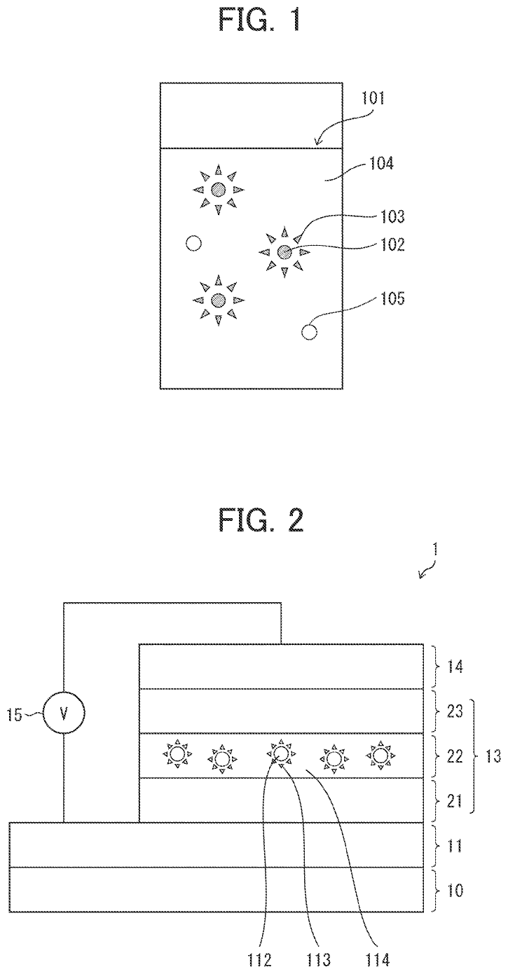

An embodiment of the present disclosure will be described below, with reference to FIGS. 1 to 10.

Note that, in the present disclosure, the statement “A to B” as to two numbers A and B means

“A or more and B or less” unless otherwise specified.

A nanoparticle composition according to the present disclosure contains, out of nanoparticles and ligands, at least the nanoparticles, and a curable monomer. At least the nanoparticles or the ligands contained in the nanoparticle composition contain aromatic rings, and the curable monomer contains an aromatic monomer.

A nanoparticle-containing film according to the present disclosure is made of the nanoparticle composition. The nanoparticle composition does not contain a solvent. The nanoparticle-containing film is formed of the nanoparticle composition. When the nanoparticle composition is applied, at least a portion of the curable monomer contained in the applied nanoparticle composition is cured. This is how the nanoparticle-containing film can be formed (produced) without a solvent. Hence, the nanoparticle-containing film contains: out of the nanoparticles and the ligands, at least the nanoparticles; and a cured resin. Then, at least the nanoparticles or the ligands contained in the nanoparticle-containing film contain aromatic rings, and the cured resin contains an aromatic polymer.

This embodiment exemplifies below a case where: the nanoparticle composition contains nanoparticles, ligands, and a curable monomer; the ligands contain aromatic ligands containing aromatic rings; and the curable monomer contains an aromatic monomer.

### Nanoparticle Composition

FIG. 1 is a cross-sectional view schematically illustrating an example of a nanoparticle composition 101 according to this embodiment.

As illustrated in FIG. 1, the nanoparticle composition 101 according to this embodiment contains at least: nanoparticles 102; ligands 103; and a curable monomer 104. Note that, in FIG. 1, the nanoparticles 102 and the ligands 103 are illustrated larger in size and smaller in number.

The nanoparticles 102 used in this embodiment may be any given nanoparticles as long as the nanoparticles 102 have a nano-size particle diameter, and can be coordinated with the ligands 103. Examples of the nanoparticles 102 include quantum dots (semiconductor quantum dots) and inorganic nanoparticles capable of transporting carriers. Note that, hereinafter, the quantum dots are referred to as “QDs”.

The QDs are a light-emitting material excited by excitons to emit light. The QDs used in this embodiment are also referred to as semiconductor nanoparticles because the QDs are inorganic-based semiconductor quantum dots having a nano-size particle diameter (e.g., a particle diameter of approximately several namometers to several tens of namometers) and the composition of the QDs is derived from a semiconductor material. Furthermore, the QDs are also referred to as nanocrystals because the QDs have a specific crystal structure. Moreover, the QDs are also referred to as fluorescent nanoparticles or QD phosphor particles because the QDs emit fluorescence and have a size by nano-order.

The QDs shall not be limited to particular QDs, and may include various known semiconductor quantum dots. The QDs may contain a semiconductor material made of at least one element selected from the group consisting of, for example, cadmium (Cd), sulfur(S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg).

Furthermore, the QDs may be binary-core QDs, tertiary-core QDs, or quaternary-core QDs.

Each of the QDs may be a core-shell QD or a core-multishell QD having a core-shell structure including a core and a shell. The shell is provided, for example, outside to coat the core.

Moreover, the QDs may contain doped nanoparticles, or may have a composition-graded structure in which the composition alters gradually. An emission wavelength of the QDs can alter in various manners depending on, for example, the diameter and the composition of the particles.

Examples of the QDs include QDs having a core-shell structure made of cadmium selenide (CdSe) and zinc sulfide (ZnS).

However, this embodiment shall not be limited to the above example. Examples of the QDs may include QDs each having a core made of, for example, CdSe, indium phosphide (InP), zinc selenide (ZnSe), and copper indium gallium selenide (CIGS, CulnₓGa₍₁₋ₓ₎Se₂). Furthermore, the QDs may have a core-shell structure such as, for example, CdSe—ZnS (zinc sulfide), CdSe—CdS (cadmium sulfide), InP—ZnS, ZnSe—ZnS, or CIGS—ZnS.

Moreover, examples of the nanoparticles capable of transporting carriers include inorganic nanoparticles capable of transporting holes and inorganic nanoparticles capable of transporting electrons. The inorganic nanoparticles capable of transporting the holes are used as a hole-transporting material. The inorganic nanoparticles capable of transporting the electrons are used as an electron-transporting material.

Examples of the inorganic nanoparticles capable of transporting the holes include nanoparticles made of, for example, a p-type semiconductor material. Examples of the p-type semiconductor material include NiO and MgNiO.

Furthermore, examples of the inorganic nanoparticles capable of transporting the electrons include fine particles made of an n-type semiconductor material. Examples of the n-type semiconductor material include ZnO, MgZnO, LiZnO, MgLiZnO, and TiO₂.

The ligands 103 are a surface modifier coordinated to, and modifying, the surface of the nanoparticles 102. The surface of the nanoparticles 102 is coordinated with the ligands 103 preferably in large amount.

Note that, in the present disclosure, the term “coordinated” means that the ligands 103 are adsorbed onto the surface of the nanoparticles 102 (i.e., the ligands 103 modify the surface of (surface-modify) the nanoparticles 102). Hence, as described above, a case where the ligands 103 are coordinated to the surface of the nanoparticles 102 indicates that the ligands 103 are adsorbed onto the surface of the nanoparticle 102 (i.e., the ligands 103 surface-modify the nanoparticles 102).

Note that, here, the term “adsorbed” means that the concentration of the ligands 103 is higher on the surface of the nanoparticles 102 than in the surroundings of the surface. The adsorption may be chemisorption representing a chemical bond between the nanoparticles 102 and the ligands 103, or may be either physisorption or electrostatic adsorption. The ligands 103 may bond to the surface of the nanoparticles 102 by, for example, coordinate boding, common bonding, ionic bonding, and hydrogen bonding as long as the adsorption of the ligands 103 chemically affect the surface of the nanoparticles 102. Alternatively, the ligands 103 do not necessarily have to bond to the surface. Furthermore, in the present disclosure, the term “ligands” collectively refers not only to molecules or ions coordinated to the surface of the nanoparticles 102 but also to molecules or ions which can be coordinated but are not coordinated.

A ligand generally includes: a coordinating functional group (an adsorbing group) coordinated to (adsorbed onto) the surface of a nanoparticle; and a carbon chain such as a hydrocarbon chain bonding to the coordinating functional group.

In this embodiment, each of the ligands 103 is an aromatic ligand containing an aromatic ring. That is, in the ligand 103, the carbon chain bonding to the coordinating functional group includes an aromatic ring.

The coordinating functional group may be a functional group coordinatable to a nanoparticle 102. Examples of the coordinating functional group typically include at least one functional group selected from the group consisting of a thiol group (a mercapto group), an amino group, a carboxyl group, a phosphone group, and a phosphine group. The thiol group is more likely to be coordinated to nanoparticles containing Zn such as CdSe-ZnS described above than, for example, to the amino group, the carboxyl group, the phosphone group, and the phosphine group. Hence, the coordinating functional group is preferably, for example, the thiol group. The ligand 103 has at least one coordinating functional group described above.

Furthermore, the aromatic ring is preferably a benzene ring. As the aromatic ring ligand, for example, thiophenols are preferably used.

Thiophenols have a structure in which at least one hydrogen in a benzene ring is substituted with a mercapto group, and a thiol group directly bonds to the benzene ring. Examples of the thiophenols include at least one selected from the group consisting of benzenethiol, 1,2-benzenedithiol, 1,3-benzenedithiol, 1,4-benzenedithiol, methyl 4-mercaptobenzoate, and 4-mercaptobenzoic acid.

If the nanoparticles 102 are, for example, QDs, ligands such as, for example, oleic acid and trioctylphosphine are used for synthesis of the QDs by solution processing. Furthermore, a commercially available QD-dispersed solution (a QD colloidal solution) contains ligands such as, for example, oleic acid and trioctylphosphine in order to improve surface stability, or preservation stability, of QDs. Note that, hereinafter the term “original ligands” refers to ligands contained either in a synthesized or commercially available nanoparticle-dispersed solution (i.e., ligands coordinated either to synthesized or commercially available nanoparticles). As can be seen, the original ligands in many cases are non-aromatic ligands in which aliphatic hydrocarbon chains bond to coordinating functional groups.

Thus, if the nanoparticles 102 are, for example, QDs, ligand substitution is required in many cases. Hence, the surface of the nanoparticles 102 may be coordinated with non-aromatic ligands not containing aromatic rings, in addition to the aromatic ligands.

Note that, in order to express a sufficient x-x stacking, a proportion (a content) of aromatic ligands having aromatic rings in the ligands 103 on the surface of the nanoparticles 102 is preferably 10 w % or more, and more preferably 50 wt % or more. Most preferably, all of the ligands are aromatic ligands.

Furthermore, a sum of contents of the nanoparticles 102 and the aromatic ligands in the nanoparticle composition 101 is preferably in a range of 0.01 wt % or more and 10 wt % or less.

Moreover, in this embodiment, the curable monomer 104 is an aromatic monomer containing aromatic rings.

As the aromatic rings, benzene rings are preferable. As the curable monomer 104, a benzene-based aromatic monomer is preferable.

Note that the aromatic monomer may be a polycyclic aromatic monomer such as, for example, perylene. However, an aromatic monomer with no aromatic ring is condensed is likely to disperse the nanoparticles 102.

An aromatic ring has a structure in which carbons having x electrons are arranged circularly.

The nanoparticles 102 are modified with the ligands 103 having aromatic rings, and an aromatic monomer having aromatic rings is used as the curable monomer 104. Hence, the x-x stacking between the aromatic rings of the ligands 103 and the aromatic rings of the curable monomer 104 successfully keep the nanoparticles 102 from agglomerating together. Thus, according to this embodiment, this noncovalent-bonding x-x stacking allows the nanoparticles 102, which are coordinated with the ligands 103, to directly disperse into the curable monomer 104 without a solvent.

The curable monomer 104 may be either a photo-curable monomer or a thermo-setting monomer as long as the curable monomer 104 contains an aromatic monomer. That is, the curable monomer 104 may contain at least one selected from the group consisting of a photo-curable monomer having aromatic rings, a photo-curable oligomer having aromatic rings, a thermo-setting photo-curable monomer having aromatic rings, and a thermo-setting oligomer having aromatic rings. These curable monomers may be used alone, or in combination of two or more as appropriate.

Among the aromatic monomers, the photo-curable monomer is more preferable as the curable monomer 104. It is because the photo-curable monomer reacts to activation energy rays such as an ultraviolet (UV) ray, and is cured and bonded to form a resin cured-product layer.

Furthermore, the photo-curable monomer may be either a radical polymerizable monomer or a cationic polymerizable monomer. However, in view of costs and curability, the photo-curable monomer is more preferably a photo-radical polymerizable monomer.

Hence, the curable monomer 104 may have in the molecules either a photo-curable functional group or a thermo-setting functional group serving as a curable functional group. However, the curable monomer 104 preferably has at least a photo-curable functional group, and, more preferably, has a radical-curable group.

A (meth) acryloyl group, which is a radical curable functional group (a photo-radical polymerizable functional group), excels in reactivity and works with various kinds of commercially available photo-radical polymerization initiators. Thus, the (meth) acryloyl group is easily adjustable for curing state. Hence, as the photo-curable functional group, the (meth) acryloyl group is particularly preferable.

Thus, the aromatic monomer used as the curable monomer 104 is more preferably a (meth) acrylate-based monomer having at least one (meth) acryloyl group.

Note that, in the present disclosure, the (meth) acryloyl group is an acryloyl group and/or a methacryloyl group. Furthermore, the (meth) acrylate-based monomer is an acrylate-based monomer and/or a methacrylate-based monomer. Moreover, the acrylate-based monomer is an acrylate-based monomer and/or an acrylate-based oligomer, and the methacrylate-based monomer is a methacrylate-based monomer and/or a methacrylate-based oligomer.

Examples of the (meth) acrylate-based monomer include a diacrylate derivative. Examples of the diacrylate derivative include a compound represented by a structural formula (1) below.

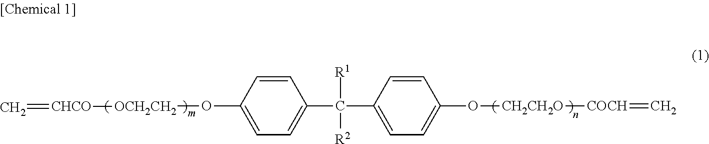

Note that, wherein in the structural formula (1), each of R¹ and R² independently represents a hydrogen atom or a methyl group. The sum of the repeating units represented by n and m is preferably 4 (i.e., n+m=4). Furthermore, each of R¹ and R² is preferably a hydrogen atom.

Note that, the (meth) acrylate-based monomer shall not be limited to the diacrylate derivative, and may have at least one (meth) acryloyl group. Examples of the (meth) acrylate-based monomer having one (meth) acryloyl group include a compound represented by a structural formula below.

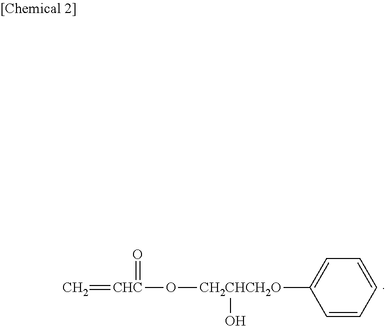

Note that, for curing the curable monomer 104, a polymerization initiator 105 may be used as necessary. Hence, as illustrated in FIG. 1, the nanoparticle composition 101 may further include the polymerization initiator 105. Note that FIG. 1 schematically illustrates the polymerization initiator 105. The polymerization initiator 105 is, for example, a powdery polymerization initiator. However, the polymerization initiator 105 does not have to be powdery. Furthermore, the polymerization initiator 105 is not necessarily found in the form of particles. Furthermore, in FIG. 1, the polymerization initiator 105 is illustrated larger in size and smaller in number of particles.

If, as described above, the curable monomer 104 is a photo-curable monomer, the polymerization initiator 105 is preferably a photopolymerization initiator. If the curable monomer 104 is a photo-radical polymerizable monomer, the photopolymerization initiator 105 is preferably a photo-radical polymerization initiator. Furthermore, the polymerization initiator 105 also preferably has aromatic rings.

Examples of the polymerization initiator 105 include an acylphosphine-oxide-based photopolymerization initiator. Examples of the acylphosphine-oxide-based photopolymerization initiator include an acylphosphine-oxide-based photopolymerization initiator such as a compound represented by a structural formula (2) below.

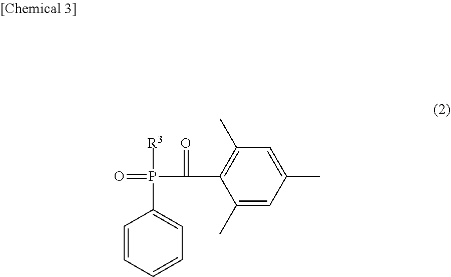

wherein R^{3 represents a group}

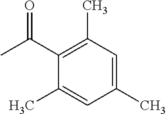

or a group

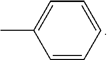

Examples of the acylphosphine-oxide-based photopolymerization initiator represented by the structural formula (2) above include: a compound (bis (2,4,6-trimethylbenzoyl) phenylphosphine oxide) represented by a structural formula (3) below; and a compound (2,4,6-trimethylbenzoyl-diphenylphosphine oxide) represented by a structural formula (4) below.

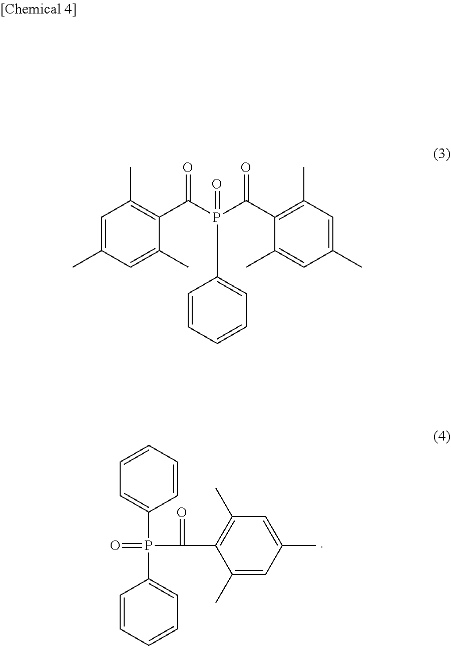

The polymerization initiator 105 has aromatic rings (benzene rings). Hence, the x-x stacking occurs between the aromatic rings of the ligands 103, the aromatic rings of the curable monomer 104, and the aromatic rings of the polymerization initiator 105. Thus, according to this embodiment, this noncovalent-bonding x-x stacking allows the polymerization initiator 105 to disperse into the nanoparticles 102 and the curable monomer 104 without a solvent.

A content of the polymerization initiator 105 with respect to the curable monomer 104 may be appropriately set depending on the kind and the amount of the curable monomer 104. In order to cure the curable monomer 104 to obtain a cured-product layer, the content is preferably in a range of 0.01 wt % or more and 10 wt % or less.

Hence, if the curable monomer 104 contains a photo-curable monomer, the content of the photopolymerization initiator with respect to the photo-curable monomer is preferably in a range of 0.01 wt % or more and 10 wt % or less.

The curable monomer 104 is a main component of the nanoparticle composition 101. The cured resin (a curable polymer) formed when the curable monomer 104 is cured is used as a binder resin for bonding together the nanoparticles 102 coordinated with the ligands 103. Hence, a proportion of the curable monomer 104 to the nanoparticle composition 101 is preferably in a range of 60 wt % or more and 99.98 wt % or less, and, more preferably, in a range of 88.5 wt % or more and 99.8 wt % or less.

Note that, in order to express a sufficient x-x stacking, a proportion of the aromatic monomer to the curable monomer 104 is preferably 51 wt % or more, and more preferably, 80 wt % or more. Most preferably, all of the curable monomer 104 is the aromatic monomer.

Furthermore, if the nanoparticles 102 are QDs and the nanoparticle composition 101 is a QD composition used for forming a light-emitting layer, a proportion of the sum of the compounds having aromatic rings (i.e., aromatic compounds) and contained in the nanoparticle composition 101 is preferably 50 wt % or more. In this case, all the substances other than the QDs are preferably compounds having aromatic rings.

Note that, here, the case where the nanoparticle composition 101 is a QD composition used for forming a light-emitting layer is a case where a nanoparticle-containing film made of the nanoparticle composition 101 is a light-emitting layer of a light-emitting element. Furthermore, the compounds having aromatic rings and contained in the nanoparticle composition 101 include: ligands included in the ligands 103 and having aromatic rings; a curable monomer included in the curable monomer 104 and having aromatic rings; and a polymerization initiator included in the polymerization initiator 105 and having aromatic rings.

Note that the nanoparticle composition 101 of this embodiment shall not be limited to the above examples. The nanoparticle composition 101 may contain various known additives such as an ultraviolet absorber and a light stabilizer as necessary unless otherwise inhibiting the x-x stacking.

### Nanoparticle-Containing Film

A nanoparticle-containing film according to this embodiment is made of the nanoparticle composition 101. Hence, the nanoparticle-containing film according to this embodiment contains at least: the nanoparticles 102; the ligands 103; and a cured resin obtained when the curable monomer 104 is cured.

Described below will be an exemplary case where: the nanoparticles 102 are fluorescent QDs; the nanoparticle composition 101 is a QD composition containing the QDs serving as a light-emitting material; the nanoparticle-containing film is a light-emitting layer of a light-emitting element, and the light-emitting element is a quantum-dot light-emitting diode (QLED) containing the QDs serving as the light-emitting material.

### Light-Emitting Element

FIG. 2 is a cross-sectional view of a schematic configuration of a light-emitting element 1 according to this embodiment.

As illustrated in FIG. 2, the light-emitting element 1 according to this embodiment is an electroluminescent element that emits light when a voltage is applied. The light-emitting element 1 includes: a first electrode 11; a second electrode 14; and a functional layer 13 (an EL layer) provided between the first electrode 11 and the second electrode 14 and including at least a light-emitting layer 22. Note that, in this embodiment, the layers between the first electrode 11 and the second electrode 14 are collectively referred to as functional layers.

The functional layer 13 may be either a single layer including the light-emitting layer 22 alone, or a multilayer including a functional layer other than the light-emitting layer 22. In the functional layer 13, examples of the functional layers other than a QD layer 15 include: carrier injection layers such as a hole injection layer and an electron injection layer; carrier transport layers such as a hole transport layer and an electron transport layer; and blocking layers such as a hole blocking layer and an electron blocking layer.

Note that, in the present disclosure, a direction from the first electrode 11 toward the second electrode 14 in FIG. 2 is referred to as an upward direction, and a direction opposite the upward direction is referred to as a downward direction. Hence, the first electrode 11 is a lower electrode and the second electrode 14 is an upper electrode.

Each of the layers from the first electrode 11 to the second electrode 14 is typically supported by a substrate serving as a support. Hence, the light-emitting element 1 may include a substrate as the support.

In the light-emitting element 1 illustrated in FIG. 2, the functional layer 13 includes, as an example, a first carrier transport layer 21, the light-emitting layer 22, and a second carrier transport layer 23. The light-emitting element 1 illustrated in FIG. 2 has a structure in which a substrate 10, the first electrode 11, the first carrier transport layer 21, the light-emitting layer 22, the second carrier transport layer 23, and the second electrode 14 are stacked on top of another in the stated order from below upwards.

Described below will be each of the above layers in more detail.

The substrate 10 described above is a support for forming each of the layers from the first electrode 11 to the second electrode 14.

Note that the light-emitting element 1 may be used as a light source of, for example, such an electronic device as a display device. If the light-emitting element 1 is, for example, a portion of a display device, a substrate of the display device is used as the substrate 10. Hence, the light-emitting element 1 may be referred to as the light-emitting element 1 with the substrate 10 included therein, or may be referred to as the light-emitting element 1 without the substrate 10.

As can be seen, the light-emitting element 1 itself may include the substrate 10. The substrate 10 included in the light-emitting element 1 may be a substrate of such an electronic device as a display device including the light-emitting element 1.

In a bottom-emission (BE) light-emitting element having a BE structure, light emitted from the light-emitting layer 22 is released downwards (i.e., toward the substrate 10). In a top-emission (TE) light-emitting element having a TE structure, light emitted from the light-emitting layer 22 is released upwards (i.e., across from the substrate 10). In a double-sided light-emitting element, light emitted from the light-emitting layer 22 is released downwards and upwards.

If the light-emitting element 1 is a BE light-emitting element or a double-sided light-emitting element, the substrate 10 is made of a light-transparent substrate relatively highly transparent to light. The substrate 10 is, for example, a glass substrate.

Whereas, if the light-emitting element 1 is a TE light-emitting element, the substrate 10 may be made of a substrate not relatively transparent to light, such as, for example, a plastic substrate. Alternatively, the substrate 10 may be a light-reflective substrate reflective to light. Note that, as to the TE structure, the light-emitting surface does not have many obstacles to light, such as TFTs. Hence, the TE structure can have a large aperture ratio, and further increase in external quantum efficiency.

Of the first electrode 11 and the second electrode 14, an electrode provided toward a light-releasing face needs to be transparent to light. Hence, at least one of the first electrode 11 or the second electrode 14 is made of a light-transparent material. Note that either the first electrode 11 or the second electrode 14 may be formed of a light-reflective material.

For example, if the light-emitting element 1 is a BE light-emitting element, the second electrode 14 is a light-reflective electrode and the first electrode 11 electrode is a light-transparent electrode. If the light-emitting element 1 is a TE light-emitting element, the second electrode 14 is a light-light-transparent electrode and the first electrode 11 is a light-reflective electrode. Note that the light-transparent electrode may be either a transparent electrode made of a light-transparent material such as a transparent conductive material, or a translucent electrode made of thin metal film or alloy. The light-reflective electrode may be a multilayer stack including a layer made of a light-transparent material such as a transparent conductive material and a light-reflective material such as metal or alloy.

Furthermore, the first electrode 11 may have an edge covered with a not-shown edge cover.

One of the first electrode 11 or the second electrode 14 is an anode, and another one is a cathode. The first electrode 11 and the second electrode 14 are connected to a power supply 15 (e.g., a DC power supply), so that a voltage is applied between the first electrode 11 and the second electrode 14.

The anode receives a voltage and supplies holes to the light-emitting layer 22. The anode is made of, for example, a material having a relatively large work function. Examples of the material include, for example, tin-doped indium oxide (ITO), zinc-doped indium oxide (IZO), aluminum-doped zinc oxide (AZO), gallium-doped zinc oxide (GZO), antimony-doped tin oxide (ATO), gold (Au), platinum (Pt), silver (Ag), and copper (Cu). These materials may be used alone or in combination of two or more as appropriate.

The cathode receives a voltage and supplies electrons to the light-emitting layer 22. The cathode is made of, for example, a material having a relatively small work function. Examples of the material include, for example, lithium (Li), calcium (Ca), barium (Ba), aluminum (Al), ytterbium (Yb), a lithium (Li)—Al alloy, a magnesium (Mg)—Al alloy, a Mg—Ag alloy, a Mg-indium (In) alloy, and an Al-aluminum-oxide (Al₂O₃) alloy.

If the first electrode 11 is an anode and the second electrode 14 is a cathode, a hole transport layer is formed as the first carrier transport layer 21 and an electron transport layer is formed as the second carrier transport layer 23. If the first electrode 11 is a cathode and the second electrode 14 is an anode, an electron transport layer is formed as the first carrier transport layer 21 and a hole transport layer is formed as the second carrier transport layer 23.

Hence, the light-emitting element 1 may include: an anode as the first electrode 11; a hole transport layer as the first carrier transport layer 21; the light-emitting layer 22; an electron transport layer as the second carrier transport layer; and a cathode as the second electrode 14, all of which are stacked on top of another in the stated order above the substrate 10. Furthermore, the light-emitting element 1 may also include: a cathode as the first electrode 11; an electron transport layer as the first carrier transport layer 21; the light-emitting layer 22; a hole transport layer as the second carrier transport layer 23; and an anode as the second electrode 14, all of which are stacked on top of another in the stated order above the substrate 10.

The hole transport layer transports the holes, supplied from the anode, to the light-emitting layer 22. The hole transport layer is made of a hole transporting material. The hole transporting material shall not be limited to a particular material, and various known hole transporting materials can be used. The hole transporting material may be an organic material such as PEDOT: PSS (poly (3,4-ethylenedioxythiophene)-poly (4-styrenesulfonate)), PVK (polyvinylcarbazole), and poly[(9,9-dioctylfluorenyl-2,7-diyl)-co-(4,4′-(N-(4-sec-butylphenyl)diphenylamine))] (TFB). Alternatively, the hole transporting material may be an inorganic material such as the p-type semiconductor material. Furthermore, these hole transporting materials may be used alone, or in combination of two or more as appropriate.

The electron transport layer transports the electrons, supplied from the cathode, to the light-emitting layer 22. The electron transport layer is made of an electron transporting material. The electron transporting material shall not be limited to a particular material, and various known electron transporting materials can be used. The electron transporting material may be, for example, either organic materials such as 1,3,5-tris (1-phenyl-1H-benzimidazol-2-yl) benzene (TPBi) and bathophenanthroline (Bphen), or inorganic materials such as the n-type semiconductor material. Furthermore, these electron transporting materials may be used alone, or in combination of two or more as appropriate.

As described above, the light-emitting layer 22 is made of a QD composition serving as the nanoparticle composition 101. The light-emitting layer 22 is a QD-containing film (a nanoparticle-containing film) containing QDs 112 serving as the nanoparticles 102. The light-emitting layer 22 contains: the QDs 112 as the nanoparticles 102; ligands 113 as the ligands 103; and a cured resin 114 (a curable polymer) obtained when the curable monomer 104 is cured. Note that, in FIG. 2, the QDs 112 and the ligands 113 are illustrated larger in size and smaller in number.

The light-emitting layer 22 is a QD light-emitting layer containing the QDs 112 as a light-emitting material. Holes and electrons recombine together in the light-emitting layer 22 by a drive current between the anode and the cathode, which forms an exciton. While the exciton transforms from the conduction band level to the valence band level of the QDs 112, light is released.

The QDs 112 are the QDs exemplified as the nanoparticles 102. The ligands 113 are the ligands exemplified as the ligands 103.

The cured resin 114 is, as described above, a cured product obtained when the curable monomer 104 is cured as described above. Because the curable monomer 104 is an aromatic monomer, the cured resin 114 contains an aromatic polymer containing aromatic rings.

The cured resin 114 functions as a binder resin for bonding together the QDs 112 coordinated with the ligands 113. The QDs 112 coordinated with the ligands 113 disperse in the cured resin 114.

As can be seen, the curable monomer 104 may be either a photo-curable monomer or a thermosetting monomer as long as the curable monomer 104 contains an aromatic monomer. Hence, the cured resin 114 may be either a photo-cured resin (a photo-curable polymer) or a thermo-set resin (a thermosetting polymer) as long as the cured resin 114 contains an aromatic polymer. Furthermore, these cured resins may be used alone, or in combination of two or more as appropriate.

Moreover, the aromatic polymer is more preferably a (meth) acrylate-based polymer having at least one (meth) acryloyl group. The (meth) acrylate-based polymer is obtained when the (meth) acrylate-based monomer having at least one (meth) acryloyl group is cured.

Note that the polymerization initiator 105 used for curing the curable monomer 104 is a portion of the cured resin 114 obtained through, for example, decomposition by activation. For example, if the polymerization initiator 105 is a photopolymerization initiator, the polymerization initiator 105 absorbs, for example, ultraviolet rays to be activated, and reacts with the curable monomer 104 to form the portion of the cured resin 114 to be obtained.

Furthermore, as can be seen, if the nanoparticle-containing film is the light-emitting layer 22, a proportion of the sum of the compounds having aromatic rings (i.e., aromatic compounds) and contained in the nanoparticle composition 101 (i.e., a QD composition) is preferably 50 wt % or more. Hence, a proportion of the sum of the compounds having aromatic rings and contained in the light-emitting layer 22 is desirably 50 wt % or more. More desirably, all the compounds have aromatic rings except for the QDs 112.

Note that, here, the compounds having aromatic rings and contained in the light-emitting layer 22 are derived from compounds having aromatic rings and contained in the QD composition. That is, the compounds having aromatic rings and contained in the light-emitting layer 22 are, for example, ligands having aromatic rings and contained in the ligands 113, and a cured resin having aromatic rings and contained in the cured resin 114. Depending on a reaction state, the compounds contain: an aromatic monomer contained in the unreacted curable monomer 104; an aromatic oligomer; and a polymerization initiator having aromatic rings and contained in the unreacted polymerization initiator 105.

As will be described later, the light-emitting layer 22 is formed of a QD composition containing: the QDs 112; the ligands 113; the curable monomer 104; and, as necessary, the polymerization initiator 105. The QD composition is applied to an underlayer (e.g., the first carrier transport layer 21 in FIG. 2) serving as a support of the light-emitting layer 22. When the curable monomer 104 is at least partially cured, the QD composition forms the light-emitting layer 22.

In the light-emitting element 1, a forward voltage is applied between the anode and the cathode. In other words, the anode is set higher in potential than the cathode. Hence, (i) the electrons can be supplied from the cathode to the light-emitting layer 22, and (ii) the holes can be supplied from the anode to the light-emitting layer 22. As a result, the light-emitting layer 22 can generate light L while the holes and the electrons recombine together. The application of the voltage may be controlled by a not-shown thin-film transistor (TFT). As an example, a TFT layer including a plurality of TFTs may be formed in the substrate 10.

Furthermore, the light-emitting element 1 may be sealed after the layers have been deposited up to the second electrode 14. The sealing member may be, for example, glass or plastic. The sealing member is, for example, concave so that a multilayer stack from the substrate 10 to the second electrode 14 can be sealed. For example, a sealing adhesive (e.g., an epoxy-based adhesive) is applied between the sealing member and the substrate 10. After that, the sealing member and the substrate 11 are sealed in a nitrogen (N₂) atmosphere. This is how the light-emitting element 1 is produced.

Note that the thickness of each layer in the light-emitting element 1 shall not be limited to a particular thickness, and can be set in the same manner as known set.

### Methods for Producing Light-Emitting Element 1 and QD-Containing Film

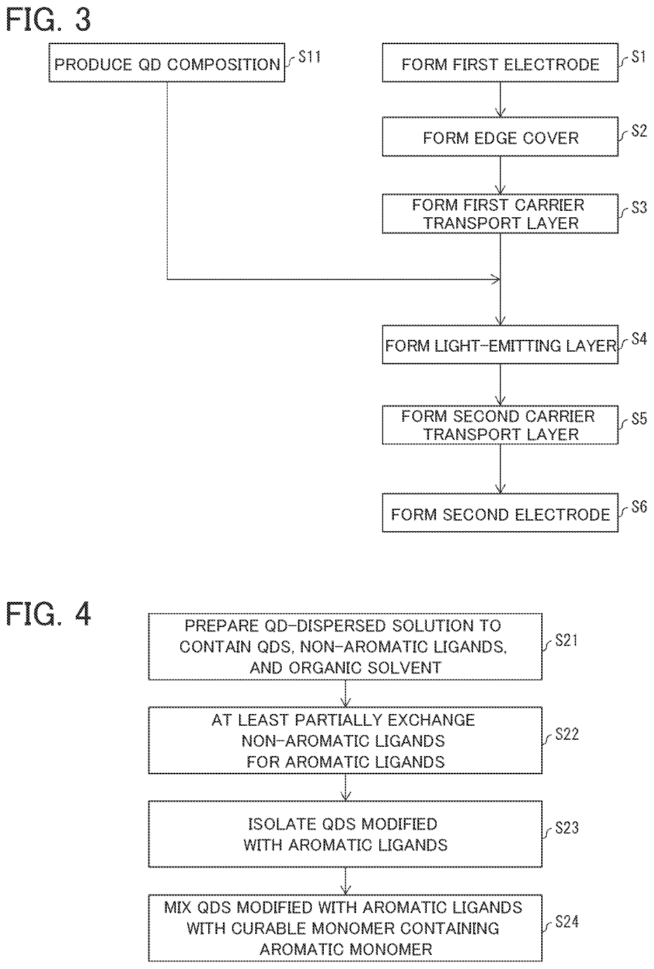

Next, a method for producing the QD-containing film will be described, citing, as an example, a method for producing a light-emitting layer formed in the process of producing the light-emitting element 1. FIG. 3 is a flowchart showing an example of a method for producing the light-emitting element 1 according to this embodiment. Note that FIG. 3 shows, as an example, a method for producing the light-emitting element 1 illustrated in FIG. 2. Furthermore, described below will be a case where the first electrode 11 has an edge covered with a not-shown edge cover.

As illustrated in FIG. 3, in the method for producing the light-emitting element 1 according to this embodiment, first, as an example, the first electrode 11 is formed on the substrate 10 (Step S1: a first electrode forming step). Next, a not-shown edge cover is formed to cover an edge of the first electrode 11 (Step S2: an edge cover forming step). Next, the first carrier transport layer 21 is formed (Step S3: a first carrier transport layer forming step). Furthermore, as the nanoparticle composition 101, the QD composition 111 is separately produced (prepared) to contain: the QDs 112; the ligands 113; the curable monomer 104; and, as necessary, the polymerization initiator 105 (Step S11: a QD composition producing step). Then, after Steps S3 and S11, the QD composition 111 is used to form the light-emitting layer 22 serving as a QD-containing film (Step S4: a light-emitting layer forming step). Next, the second carrier transport layer 23 is formed (Step S5: a second carrier transport layer forming step). Next, the second electrode 14 is formed (Step S6: a second electrode forming step).

At Steps S1 and S6, the first electrode 11 and the second electrode 14 are deposited by, for example, vapor deposition or sputtering.

At Step S2, the edge cover is made of an insulating material deposited by, for example, vapor deposition or sputtering. After that, the deposited insulating material is patterned by, for example, photolithography to form the edge cover having a desired shape.

Furthermore, at Step S3, if the first carrier transport layer 21 is made of an inorganic material, the first carrier transport layer 21 is ideally deposited by, for example, sputtering, sol-gel process, spin coating, or inkjet printing. Moreover, at Step S3, if the first carrier transport layer 21 is made of an organic material, the first carrier transport layer 21 is ideally deposited by, for example, vapor deposition, spin coating, or inkjet printing.

At Step S5, the second carrier transport layer 23 is deposited by the same technique as the technique used for depositing the first carrier transport layer 21. That is, if the second carrier transport layer 23 is an inorganic film made of an inorganic material, the inorganic film is ideally deposited by, for example, sputtering, sol-gel process, spin coating, or inkjet printing. Furthermore, if the second carrier transport layer 23 is an organic film made of an organic material, the organic film is ideally deposited by, for example, vapor deposition, spin coating, or inkjet printing.

Note that the formation of the light-emitting layer 22 at Step S4 will be described later. As can be seen, the QD composition 111 used at Step S4 is produced in advance before Step S4 is carried out. Hence, as shown in FIG. 3, the method for producing the light-emitting element 1 further includes, before Step S4, a QD composition producing step of separately producing the QD composition 111 (Step S11: a nanoparticle composition producing step).

### Method for Producing QD Composition

Next, as a method for producing the QD composition 111, an example of above Step S11 will be described.

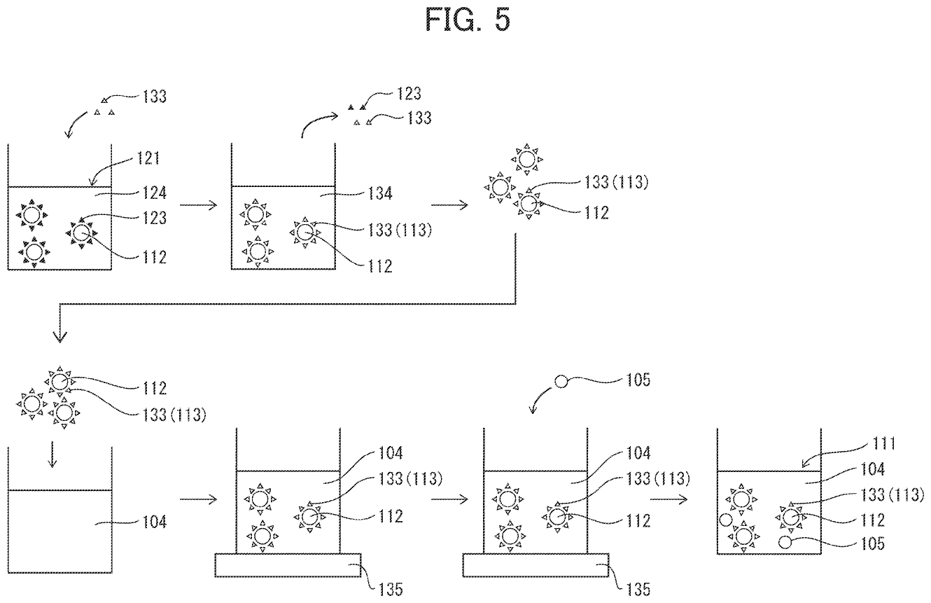

FIG. 4 is a flowchart showing an example of Step S11 (the QD composition producing step). Furthermore, FIG. 5 is a diagram schematically illustrating an example of Step 11 (the QD composition producing step) described above. Note that, in FIG. 5, the QDs 112, non-aromatic ligands 123, aromatic ligands 133, and the polymerization initiator 105 are illustrated larger in size and smaller in number of particles.

As can be seen, synthesized or commercially available QDs are, in many cases, coordinated with non-aromatic ligands such as oleic acid and trioctylphosphine serving as original ligands.

Hence, as shown in FIGS. 4 and 5, at Step S11, first, a QD-dispersed solution 121 is prepared as a nanoparticle-dispersed solution to contain: the QDs 112; the non-aromatic ligands 123; and an organic solvent 124 (Step S21: a nanoparticle-dispersed solution preparing step).

Next, as necessary, the QD-dispersed solution 121 and the aromatic ligands 133 are mixed together, so that the non-aromatic ligands 123 are at least partially exchanged for the aromatic ligands 133 (Step S22: a ligand exchanging step).

Next, impurities such as free non-aromatic ligands 123 found after the ligand exchange and excess aromatic ligands 133 not coordinated to the QDs 112 are removed for purification. As a result, the QDs 112 modified with the aromatic ligands 133 and obtained at Step S22 are isolated (Step S23: an isolating step).

Next, the QDs 112, modified with the aromatic ligands 133 and isolated at Step S23, are mixed with the curable monomer 104 containing an aromatic monomer (Step S24, a mixing step).

Note that, at Step S24, the polymerization initiator 105 may be mixed as necessary.

As a result, as the nanoparticle composition 101, the QD composition 111 can be produced to contain: the QDs 112; the ligands 113 containing the aromatic ligands 133; the curable monomer 104; and, as necessary, the polymerization initiator 105.

The non-aromatic ligands 123 contained in the QD-dispersed solution 121 are original ligands. Examples of the original ligands include oleic acid and trioctylphosphine.

The organic solvent 124 may be any organic solvent in which the QDs 112 coordinated with the non-aromatic ligands 123 can be dispersed. It is known that QDs typically degrade in water. Hence, an organic solvent is desirably used as a solvent for the QD-dispersed solution 121.

Examples of the organic solvent include non-polar solvents such as 1-octadecene and hexane.

In this embodiment, for example, the QD-dispersed solution and benzenethiol are mixed together, and the mixture is stirred at 25° C. for 24 hours. Here, the QD-dispersed solution contains, for example, core-shell QDs and 1-octadecene. The core-shell QDs are made of CdSe—ZnS and modified with common ligands such as oleic acid ligands and trioctylphosphine ligands. Thanks to the mixture, the oleic acid ligands and the trioctylphosphine ligands can be exchanged for benzenethiol.

Note that reaction conditions such as a reaction temperature and a reaction time in the above ligand exchange reaction may be appropriately set according to kinds and amounts of the non-aromatic ligands 123, the aromatic ligands 133, and the organic solvent 124, so that the ligand exchange reaction is completed. Hence, the reaction conditions shall not be limited to particular conditions.

Furthermore, the greater the concentration of the aromatic ligands 133 is in the QD-dispersed solution 121, the easier the exchange of the non-aromatic ligands 123 is for the aromatic ligands 133. Moreover, the excess aromatic ligands 133 not coordinated to the QDs 112 are rinsed and removed at Step S23 (the isolating step). Hence, the concentration of the aromatic ligands 133 in the QD-dispersed solution 121 is desirably as high as possible. Thus, the concentration of the aromatic ligands 133 shall not be limited to a particular concentration as long as the aromatic ligands 133 are supplied in excess amount over the non-aromatic ligands 123.

Note that the ligand exchange itself of non-aromatic ligands for aromatic ligands is known. For example, Non-Patent Document 1 discloses that the ligands coordinated to the QDs made of CdSe—ZnS are partially substituted with benzenethiol, so that stability of the QDs and efficiency in electroluminescence (EL) improve (i.e., quantum yield and mobility increase). The ligand exchange can be carried out by application of these known techniques.

Furthermore, if the original ligands are aromatic ligands, the ligand exchange (i.e., Step S22) does not have to be carried out.

Note that the kind of the ligands coordinated to the nanoparticles 102 such as the QDs 112 can be detected by, for example, an MS/MS spectrum of a time-of-flight secondary ion mass spectrometry (TOF-SIMS) apparatus equipped with a tandem mass spectrometer (MS/MS). When the TOF-SIMS apparatus is used to carry out tandem mass spectrometry of the nanoparticle-containing film obtained when a nanoparticle-dispersed solution such as a QD-dispersed solution is dried, the structure of molecules in a nano-order thin-film sample can be analyzed, thereby making it possible to determine with high precision a molecular structure of the ligands contained in the nanoparticle-containing film.

Furthermore, depending on the ligands to be coordinated, a measurement by Fourier transform infrared spectroscopy (hereinafter referred to as the “FT-IR measurement”) can determine whether the ligands are coordinated.

Moreover, after the ligand exchange, the peak of the ligands before the exchange (substitution) disappears and the ligands before exchange (substitution) are replaced only with the ligands after the exchange. As a result, the ligand exchange can be confirmed.

In addition, multiple analytical techniques (e.g., matrix-assisted laser desorption/ionization (MALDI)-time of flight mass spectrometry (TOF-MS), liquid chromatography-mass spectrometry (LC-MS/MS), and time of flight secondary ion mass spectrometry (TOF-SIMS)) are combined together to identify organic ligands.

At Step S23, a rinsing liquid 134 (see FIG. 5) is added to the QD-dispersed solution 121 obtained after the ligand exchange, and the QDs 112 after the ligand exchange are rinsed and purified by centrifugal separation, The rinsing liquid 134 may be either hexane or a mixed solution of hexane and absolute ethanol.

For example, first, hexane is added to the QD-dispersed solution 121 obtained after the ligand exchange, and the QD-dispersed solution 121 is subjected to centrifugal separation at 12000 rmp for 10 minutes. Hence, impurities not dispersed in the hexane solvent are removed. Next, a mixed solution of hexane and absolute ethanol (e.g., a volume ratio of hexane to absolute ethanol is 1 to 4) is used, and centrifugal separation is carried out in a similar manner. Here, a ratio of the solvent in the mixed solution; that is, for example, a ratio of hexane to absolute ethanol, is controlled so that how the QDs 112 agglomerate can be changed depending on variations in kinds and amounts of the ligands coordinated to the surface of the QDs 112. In this embodiment, as described above, the impurities not dispersed in, for example, the hexane solvent are removed. After that, using the mixture solution of the hexane and the absolute ethanol, centrifugal separation is carried out, for example, three times for purification of the QDs 112. After that, the rinsing liquid 134 serving as a solvent is evaporated and removed, and the QDs 112 modified with the aromatic ligands 133 and obtained at Step S22 are isolated in the form of powder.

At Step S24, the powder of QDs 112 modified with the aromatic ligands 133 (i.e., the powder of QDs 112 modified with the ligands 113) is mixed with the curable monomer 104 containing an aromatic monomer.

As previously described, a sum of contents of the nanoparticles 102 and the aromatic ligands in the nanoparticle composition 101 is preferably in a range of 0.01 wt % or more and 10 wt % or less. Hence, at Step S14, the powder of QDs 112 modified with the aromatic ligands 133 and the curable monomer 104 are mixed together, so that a sum of contents of the QDs 112 and the aromatic ligands 133 in the QD composition 111 is desirably within the above range.

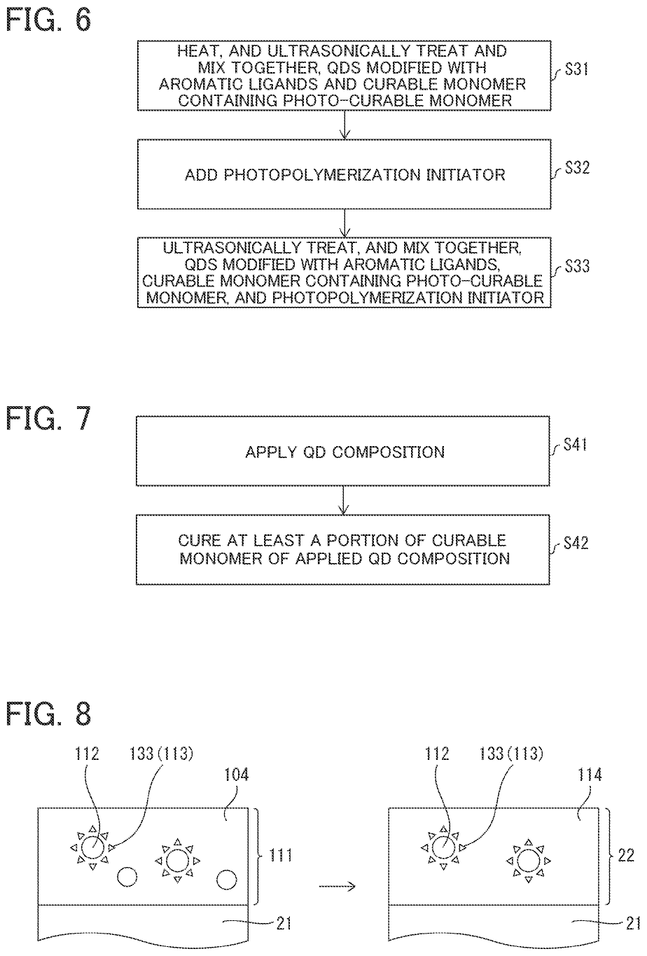

FIG. 6 is a flowchart showing an example of Step S24 (the mixing step) described above.

The mixing step preferably involves heating and mixing together the powder of QDs 112 modified with the aromatic ligands 133 and the curable monomer 104 containing the photo-curable monomer.

Hence, at Step S24, as shown in FIGS. 5 and 6, first, for example, the QDs 112 modified with the aromatic ligands 133 and the curable monomer 104 containing the photo-curable monomer are heated, and ultrasonically treated and mixed together (Step S31).

The heating temperature may be set appropriately depending on a kind of the photo-curable monomer, and shall not be limited to a particular temperature. In order to reduce the viscosity of the photo-curable monomer, the heating temperature is preferably, for example, 30° C. or higher and 60°° C. or lower.

Furthermore, the mixing time for the ultrasonic treatment may be set appropriately, so that the QDs 112 modified with the aromatic ligands 133 and the curable monomer 104 containing the photo-curable monomer are sufficiently mixed together. Hence, the mixing time for the ultrasonic treatment shall not be limited to a particular time. In order to improve dispersibility, the mixing time is preferably, for example, 10 minutes or longer and 3 hours or shorter.

As an example, in this embodiment, a mixture of the CdSe—ZnS coordinated with benzenethiol ligands and a diacrylate derivative, in which the R¹ and the R² in the structural formula (1) are hydrogen atoms, is heated at 50° C. and ultrasonically treated for one hour using an ultrasonic apparatus 135 (see FIG. 5).

Note that the ultrasonic apparatus 135 may be formed integrally with a heating apparatus, and capable of generating ultrasonic waves and heat. Alternatively, the ultrasonic apparatus 135 may be provided separately from the heating apparatus.

When photo-curable monomers such as an ultraviolet-curable monomer are heated, the photo-curable monomers can exhibit a significant decrease in viscosity and an improvement in dispersibility.

Although depending on a kind of the photo-curable monomer, for example, in the case of the diacrylate derivative in which the R¹ and the R² in the structural formula (1) are hydrogen atoms, if the diacrylate derivative is heated approximately to 15°° C. to 50° C., the viscosity of the diacrylate derivative can be reduced from, for example, approximately 1800 mPa·s to 200 to 300 mPa·s.

Furthermore, as described above, when the QDs 112 modified with the aromatic ligands 133 are dispersed once in the curable monomer 104 containing the photo-curable monomer, the dispersibility of the curable monomer 104 can be maintained for approximately one month even if the temperature of the mixture is brought back to room temperature. Note that the same applies to a case where the nanoparticles 102 are nanoparticles other than the QDs 112.

As described above, the QDs 112 are modified with the ligands 113 having aromatic rings, and an aromatic monomer having aromatic rings is used as the curable monomer 104. Hence, the x-x stacking between the aromatic rings of the aromatic ligands 133 and the aromatic rings of the aromatic monomer successfully keep the QDs 112 from agglomerating together.

Next, the polymerization initiator 105 containing a photopolymerization initiator is added to the mixture (Step S32). For example, as the polymerization initiator 105, a photopolymerization initiator is added.

After that, the QDs 112 modified with the aromatic ligands 133, the curable monomer 104 containing a photo-curable monomer, and the photopolymerization initiator are ultrasonically treated and mixed together (Step S33). Note that, during the mixing, it is desirable to remove bubbles generated in small amount.

As described above, the content of the photopolymerization initiator with respect to the curable monomer 104 is preferably in a range of 0.01 wt % or more and 10 wt % or less.

Note that, the mixing time for the ultrasonic treatment may be set appropriately, so that the mixture of the QDs 112 modified with the aromatic ligands 133 and the curable monomer 104 containing the photo-curable monomer, and the polymerization initiator 105 containing the photopolymerization initiator, are sufficiently mixed together. Hence, the mixing time for the ultrasonic treatment shall not be limited to a particular time. In order to improve dispersibility, the mixing time is preferably, for example, 10 minutes or longer and 3 hours or shorter.

As an example, in this embodiment, a mixture of the CdSe—ZnS coordinated with benzenethiol ligands and a diacrylate derivative, in which the R¹ and the R² in the structural formula (1) are hydrogen atoms, is mixed with the polymerization initiator 105; that is, a radical photopolymerization initiator (bis (2,4,6-trimethylbenzoyl) phenylphosphine oxide) represented by the structural formula (3), and heated at room temperature and ultrasonically treated for 15 minutes.

Hence, the QD composition 111 is produced.

FIG. 7 is a flowchart showing an example of Step S4 (the light-emitting layer forming step). FIG. 8 is a diagram schematically illustrating an example of Step S4 (the light-emitting layer forming step). Note that, also in FIG. 8, the QDs 112 and the aromatic ligands 133 are illustrated larger in size and smaller in number.

As shown in FIGS. 7 and 8, at Step S4, first, the QD composition 111 produced at Step S11 is applied to the underlayer (e.g., the first carrier transport layer 21 in FIG. 2) serving as the support of the light-emitting layer 22 (Step S41: an applying step).

Next, at least a portion of the curable monomer 104 of the QD composition 111 applied at Step S41 is cured (Step S42: a curing step). Step S42 forms the light-emitting layer 22 formed of the cured resin 114 in which the QDs 112 modified with the aromatic ligands 133 are thoroughly dispersed.

The QD composition 111 is applied by application techniques such as, for example, spin coating.

Note that if the light-emitting layer 22 is a light-emitting layer formed for each of a plurality of the light-emitting elements 1 included in a display device and emitting light in different colors, Step S4 forms light-emitting layers 22 each formed in any given order for a corresponding color of the emitted light.

In this case, at Step S4, a photo-curable monomer is used as the curable monomer 104. Light exposure is provided only to a portion to be the light-emitting layer 22 of a pixel corresponding to a color of light to be emitted from the QDs 112 contained in the applied QD composition 111. In the light-exposed region of the applied QD composition 111, the photo-curable monomer is crosslinked and polymerized to increase in molecular weight, and is cured to be a cured product (a solid). The light exposure described above involves, for example, masking light exposure using a mask. After that, a solvent capable of dissolving or dispersing the curable monomer 104 is used as a developing solution to remove a coating film of the QD composition 111 in a region not exposed to light.

For example, if the QD composition 111 contains blue QDs as the QDs 112, the masking light exposure is provided only to a portion included in the applied QD composition 111 and serving as the light-emitting layer 22 of a blue pixel. Other portions not exposed to light are removed. If the QD composition 111 contains green QDs as the QDs 112, the masking light exposure is provided only to a portion included in the applied QD composition 111 and serving as the light-emitting layer 22 of a green pixel. Other portions not exposed to light are removed. Likewise, if the QD composition 111 contains red QDs as the QDs 112, the masking light exposure is provided only to a portion included in the applied QD composition 111 and serving as the light-emitting layer 22 of a red pixel. Other portions not exposed to light are removed. If the display device includes, for example, red pixels, green pixels, and blue pixels as the pixels, the steps from the application of the QD composition 111 to the removal of portions not exposed to light are repeated three times. As a result, the light-emitting layers 22 are successfully formed to have three colors of red (R), green (G), and blue (B).

As can be seen, when the QD composition 111 is used, the QLEDs can be individually colored in RGB by photolithography. Such a technique can achieve higher definition than inkjet printing.

Furthermore, the QD composition 111 does not contain a solvent. Without a solvent, the light-emitting layer 22 is successfully formed of the cured resin 114 in which the QDs 112 are thoroughly dispersed. Such a feature can reduce (relieve) the coffee ring effect occurring in evaporation of the solvent, and in-plane variation observed in the light-emitting layer 22. Note that the advantageous effects to be obtained can be greater with higher definition of a pattern of a formed nanoparticle film. Moreover, as described above, this embodiment can reduce the in-plane variation observed in the light-emitting layer 22 when the solvent evaporates. Such a feature makes it possible to further planarize the surface of the light emitting layer 22. As a result, this embodiment is expected to improve adhesion between the light-emitting layer 22 and an upper layer (e.g., the second carrier transport layer 23 in FIG. 2) of the light-emitting layer 22, and to increase current injection efficiency.

### Application to Display Device

The light-emitting element 1 as described above is used ideally as a light source of, for example, such an electronic device as a display device. That is, the QD-containing film may be a light-emitting layer of the display device.

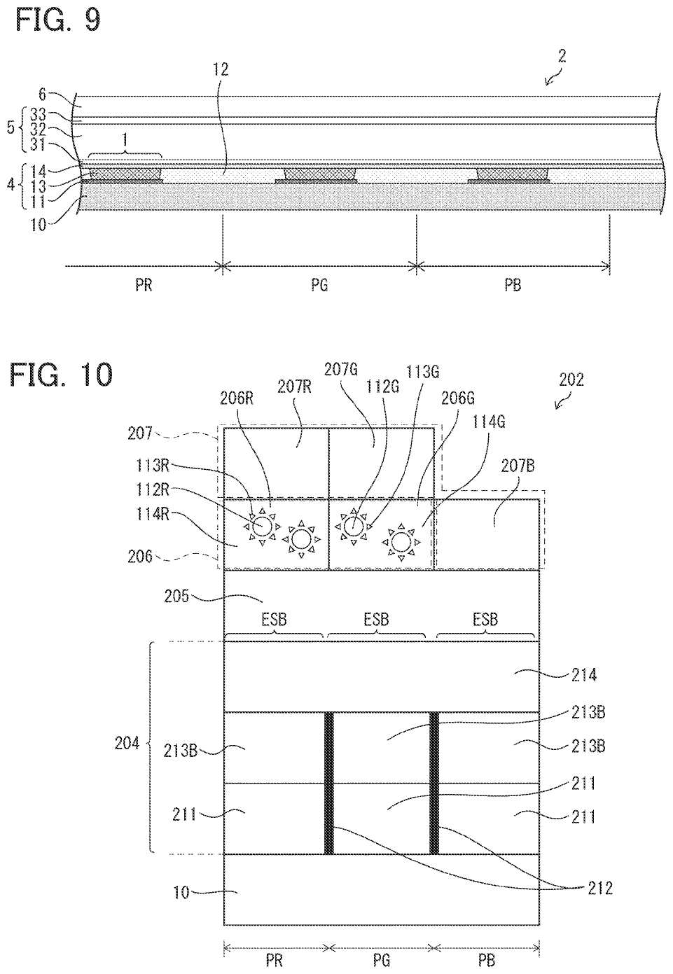

FIG. 9 is a cross-sectional view illustrating an example of a schematic configuration of a main feature of a display device 2 according to this embodiment.

The display device 2 has a plurality of pixels. Each of the pixels is provided with the light-emitting element 1. The display device 2 includes, as the substrate 10, an array substrate in which, for example, a TFT layer is formed. The display device 2 further includes: a light-emitting element layer 4 including a plurality of the light-emitting elements 1 having different emission wavelengths; a sealing layer 5; and a functional film 6, all of which are stacked on top of another in the stated order above the substrate 10.

The display device 2 illustrated in FIG. 9 includes, as pixels: a red pixel PR that emits a red light; a green pixel PG that emits a green light; and a blue pixel PB that emits a blue light. Between the pixels, for example, an edge cover 12 is provided to cover an edge of the first electrode 11 and to function as a pixel separating film for separating the neighboring pixels from one another. The edge cover 12 is insulative.

In forming the edge cover 12, for example, an organic material such as polyimide or acrylic resin is applied. After that, the applied organic material is patterned by photolithography to form the edge cover 12.

The display device 2 includes, as the plurality of light-emitting elements 1 having different emission wavelengths, a red light-emitting element that emits a red light, a green light-emitting element that emits a green light, and a blue light-emitting element that emits a blue light. The red pixel PR is provided with the red light-emitting element serving as a light-emitting element 1. The green pixel PG is provided with the green light-emitting element serving as a light-emitting element 1. The blue pixel PB is provided with the blue light-emitting element serving as a light-emitting element 1.

The light-emitting element layer 4 includes the plurality of light-emitting elements 1 provided for the respective pixels. Above the substrate 10, the layers of each of the light-emitting elements 1 are stacked on top of another.

Specifically, the light-emitting element 4 includes, for example: a plurality of first electrodes 11; a second electrode 14; a functional layer 13 provided between the first electrodes 11 and the second electrode 14; and the edge cover 12 that is insulative, all of which form the light-emitting elements 1. Each of the first electrodes 11, which functions as a so-called pixel electrode (an island-shaped lower electrode), is shaped into an island and provided on the substrate 10 for a corresponding one of the light-emitting elements 1 (i.e., the pixels). The second electrode 14, which functions as a common electrode (a common upper electrode), is provided in common to all the light-emitting elements 1 (i.e., all the pixels). The light-emitting elements 1 function as light sources to cause the pixels to emit light.

The light-emitting element layer 4 is covered with the sealing layer 5. The sealing layer 5 is transparent to light, and includes, for example, a first inorganic sealing film 31, an organic sealing film 32, and a second inorganic sealing film 33 in the stated order from below (i.e., from toward the light-emitting element layer 4). Note that the configuration of the sealing layer 5 shall not be limited to such a configuration. The sealing layer 5 may be formed of an inorganic sealing film alone, or may be a multilayer stack including five layers or more such as an organic sealing film and an inorganic sealing film. Furthermore, the sealing layer 5 may be, for example, a sealing glass. The sealing layer 5 seals the light-emitting elements 1, thereby making it possible to prevent water and oxygen from penetrating into the light-emitting elements 1.

Each of the first inorganic sealing film 31 and the second inorganic sealing film 33 can be formed of a silicon oxide film, a silicon nitride film, a silicon oxynitride film, or a multilayer film including these films. These films can be formed by, for example, chemical vapor deposition (CVD). The organic sealing film 32 is a light-transparent organic film thicker than the first inorganic sealing film 31 and the second inorganic sealing film 33. The organic sealing film 32 can be formed of an applicable photosensitive resin such as polyimide resin and acrylic resin.

Note that, as illustrated in FIG. 9, the display device 2 may include the functional film 6 provided on the sealing layer 5 and having at least one of, for example, an optical compensation function, a touch sensor function, and a protection function.

Application to Wavelength Conversion Member

Furthermore, the QD-containing film (the nanoparticle-containing film) may be a wavelength conversion layer of a wavelength conversion member. That is, the wavelength conversion member may include the QD-containing film as the wavelength conversion layer. Moreover, the display device may include the wavelength conversion member as a photoelectric converting unit.

Described below will be an exemplary case where the QD-containing film is used for a wavelength conversion layer of, for example, a wavelength conversion sheet included in the display device and serving as the wavelength conversion member.

FIG. 10 is a schematic view illustrating an example of a configuration of a main feature of a display device 202 according to this embodiment.

Similar to the display device 2 illustrated in FIG. 9, the display device 202 according to this embodiment has a plurality of pixels, and each of the plurality of pixels is provided with a light-emitting element. The display device 202 is provided with an array substrate serving as the substrate 10 in which a driving element layer is formed. The display device 202 includes: a light-emitting element layer 204 including a plurality of light-emitting elements; a sealing layer 205; a wavelength conversion sheet 206 (a wavelength conversion member); and a color filter (CF) sheet 207 (a CF member), all of which are stacked on top of another in the stated order above the substrate 10.

Similar to the display device 2, the display device 202 illustrated in FIG. 10 includes, as pixels, a red pixel PR, a green pixel PG, and a blue pixel PB. Between the pixels, an edge cover 212 is provided to serve as a pixel separating film to separate the neighboring pixels from one another. The edge cover 212 is insulative.

Each of the red pixel PR, the green pixel PG, and the blue pixel PB in the display device 202 is provided with a light-emitting element; namely, a light-emitting element ESB (a blue light-emitting element) that emits a blue light.

The light-emitting element ESB is an electroluminescent element that emits light when a voltage is applied to the light-emitting layer. The light-emitting element ESB includes: a first electrode 211; a second electrode 214; and a functional layer 213B provided between the first electrode 211 and the second electrode 214, and including a light-emitting layer that emits a blue light.

The light-emitting element layer 204 includes a plurality of the light-emitting elements ESB provided for the respective pixels. Above the substrate 10, the layers of each of the light-emitting elements ESB are stacked on top of another.

The substrate 10 functions as a support for forming the layers of each light-emitting element ESB. The substrate 10 is an array substrate, and provided with, for example, a TFT layer.

The light-emitting element layer 204 includes, as an example: a plurality of the first electrodes 211; the second electrode 214; the functional layer 213B provided between the first electrodes 211 and the second electrode 214, and at least containing a light-emitting layer; and the edge cover 212 insulative and covering an edge of each of the first electrodes 211 provided on the substrate 10.

In FIG. 10, the layers are shown in a simplified manner, and the edge cover 212 is the same in configuration as the edge cover 12. The edge cover 212 covers the edge of the patterned first electrode 211, and also functions as a pixel separating film. As an example, the first electrodes 211 and a plurality of the functional layers 213B are separated (patterned) for the respective pixels with the edge cover 212. Hence, in the light-emitting element layer 204, each of the light-emitting elements ESB is provided for a corresponding one of the pixels. The first electrode 211 of each light-emitting element ESB is electrically connected to a TFT of the substrate 10. Whereas, the second electrode 214, serving as a common electrode, is provided in common to all the pixels.

Note that the light-emitting element ESB may be a QLED. Alternatively, the light-emitting element ESB may be either an organic light-emitting diode (OLED), or an inorganic light-emitting diode (IOLED).

If the light-emitting element ESB is a QLED, the light-emitting element ESB may be the same in configuration as the light-emitting element 1 illustrated in FIG. 2. In this case, the QDs 112 illustrated in FIG. 2 are blue QDs.

If the light-emitting element ESB is either an OLED or an IOLED, the light-emitting layer is formed of, for example, either an organic light-emitting material or an inorganic light-emitting material, such as a low-molecular fluorescent (or phosphorescent) dye or a metal complex. Note that, in this case as well, the light-emitting element ESB is formed of a light-emitting material that emits a blue light.

If the light-emitting element ESB is either an OLED or an IOLED, the holes and the electrons recombine together in the light-emitting layer by a drive current between the anode and the cathode, which forms an exciton. While the exciton transforms to the ground state, light is released.

The light-emitting layer of the OLED or the IOLED can be formed, for example, by coating with separate light-emitting materials, using a fine metal mask (FMM), and evaporating the light-emitting materials, or by inkjet printing with a light-emitting material.

The light-emitting element layer 204 is covered with the sealing layer 205. The first electrode 211 is the same as the first electrode 11 in the light-emitting element 1. The second electrode 214 is the same as the second electrode 14 in the light-emitting element 1. The sealing layer 205 is the same as the sealing layer 5 in the display device 2 illustrated in FIG. 9.

The wavelength conversion sheet 206 illustrated in FIG. 10 includes: a red wavelength conversion layer 206R; and a green wavelength conversion layer 206G.

The red wavelength conversion layer 206R is provided in association with the red pixel PR. The green wavelength conversion layer 206G is provided in association with the green pixel PG.

The red wavelength conversion layer 206R and the green wavelength conversion layer 206G emit light by photoluminescence (PL).

The red wavelength conversion layer 206R contains: a plurality of QDs 112R (red QDs) that serve as the QDs 112, receive a red light emitted as an excitation light from the light-emitting element ESB, and emit the red light; and ligands 113R that serve as the ligands 113, and are coordinated to the plurality of QDs 112R. The red wavelength conversion layer 206R converts the blue light, which is emitted from the light-emitting element ESB, into a red light, and emits the red light. The QDs 112R coordinated with the ligands 113R are dispersed in a cured resin 114R.

The green wavelength conversion layer 206G contains: a plurality of QDs 112G (green QDs) that serve as the QDs 112, receive a green light emitted as an excitation light from the light-emitting element ESB, and emit the green light; and ligands 113G that serve as the ligands 113, and are coordinated to the plurality of QDs 112G. The green wavelength conversion layer 206G converts the blue light, which is emitted from the light-emitting element ESB, into a green light, and emits the green light. The QDs 112G coordinated with the ligands 113G are dispersed in a cured resin 114G.

Note that, in FIG. 10, the QDs 112R, the QDs 112G, the ligands 113R, and the ligands 113G are illustrated larger in size and smaller in number.

The QDs 112R and the QDs 112G can be the same QDs as the QDs 112. Furthermore, the ligands 113R in the red wavelength conversion layer 206R and the ligands 113G in the green wavelength conversion layer 206G can be the same ligands as the ligands 113 described in the first embodiment. A curable monomer used as a raw material of a cured resin 114R in the red wavelength conversion layer 206R and of a cured resin 114G in the green wavelength conversion layer 206G can be the same curable monomer as the curable monomer 104 used as a raw material of the cured resin 114. The cured resin 114R and the cured resin 114G, similar to the cured resin 114, are cured products. The above curable monomer is at least partially cured to form the cured resin 114R and the cured resin 114G.

As illustrated in FIG. 10, even if the nanoparticle-containing films are the red wavelength conversion layer 206R and the green wavelength conversion layer 206G, each of a proportion of the sum of compounds having aromatic rings and contained in the red wavelength conversion layer 206R and a proportion of the sum of compounds having aromatic rings and contained in the green wavelength conversion layer 206G is desirably 50 wt % or more. More desirably, all the compounds have aromatic rings except for the QDs 112R and the QDs 112G.

The red wavelength conversion layer 206R and the green wavelength conversion layer 206G can be formed by the same method as the method for forming a QD-containing film used as the light-emitting layer 22.

The CF sheet 207 includes: a red CF layer 207R; a green CF layer 207G; and a blue CF layer 207B.

The red CF layer 207R selectively transmits a red light. The red CF layer 207R has a high light transmittance in a red wavelength band, and a relatively low light transmittance in other wavelength bands. The green CF layer 207G selectively transmits a green light. The green CF layer 207G has a high light transmittance in a green wavelength band, and a relatively low light transmittance in other wavelength bands. The blue CF layer 207B selectively transmits a blue light. The blue CF layer 207B has a high light transmittance in a blue wavelength band, and a relatively low light transmittance in other wavelength bands.

In the example illustrated in FIG. 10, the red CF layer 207R is provided on the red wavelength conversion layer 206R in association with the red pixel PR, in order to further narrow an emission spectrum of a red light emitted from the red wavelength conversion layer 206R. The green CF layer 207G is provided on the green wavelength conversion layer 206G in association with the green pixel PG, in order to further narrow an emission spectrum of a green light emitted from the green wavelength conversion layer 206G. The blue CF layer 207B is provided in association with the blue light PB, in order to further narrow an emission spectrum of a blue light emitted from the light-emitting element ESB provided to the blue pixel PB.

The materials of, and the forming methods for, the red CF layer 207R, the green CF layer 207G, and the blue CF layer 207B shall not be limited to particular materials or methods. The materials and the forming methods may be known materials and forming methods. These CF layers can contain pigments, dyes, or inorganic materials. Note that the CF sheet 207 may be provided as necessary, or may be omitted.

Furthermore, as illustrated in FIG. 10, the wavelength conversion sheet 206 and the CF sheet 207 may be formed integrally with the light-emitting elements ESB as a portion of the display device 202. Alternatively, the wavelength conversion sheet 206 and the CF sheet 207 may be formed as separate single products. Moreover, the CF sheet 207 may be formed separately from the wavelength conversion sheet 206 as an independent single product, or may be formed integrally with the wavelength conversion sheet 206.

Hence, the wavelength conversion sheet 206 may further include a light-transparent support layer that supports the red wavelength conversion layer 206R and the green wavelength conversion layer 206G. The wavelength conversion sheet 206 may further include an overcoat layer and a spacer such as a photo spacer. Note that this embodiment exemplifies a case where the wavelength conversion member is a wavelength conversion sheet. Alternatively, the wavelength conversion member may include a support layer such as a glass plate or a ceramic plate.

Moreover, the wavelength conversion sheet 206 may further include a not-shown blue light-transparent layer that transmits a blue light emitted from a light-emitting element ESB. If the wavelength conversion sheet 206 is provided with the blue light-transparent layer, the blue light-transparent layer is provided in association with the blue pixel PB. Note that the blue light-transparent layer may be made of any given material. The material preferably has a high light transmittance at least in the blue wavelength band (e.g., a glass or a resin transparent to light).

Such a blue light-transparent layer can be formed by the same method as the method for forming a light-transparent layer provided to a known wavelength conversion sheet.

Note that, similarly, if the CF sheet 207 is formed as a single product formed separately from the wavelength conversion sheet 206, the CF sheet 207 may further include a light-transparent support layer that supports the red CF layer 207R, the green CF layer 207G, and the blue CF layer 207B. The CF sheet 207 may further include an overcoat layer and a spacer such as a photo spacer. Furthermore, the CF sheet 207 may include a light-transparent layer instead of some of the CF layers. The light-transparent layer may transmit light in a specific color.

Moreover, FIG. 10 exemplifies a case where the red pixel PB, the green pixel PG, and the blue pixel PB are provided with the respective light-emitting elements ESB that emit a blue light, where the red pixel PR is provided with the red wavelength conversion layer 206R containing the QDs 112R that serve as the QDs 112 and emit a red light, and where the green pixel PG is provided with the green wavelength conversion layer 206G containing the QDs 112G that serve as the QDs 112 and emit a green light. However, this embodiment shall not be limited to this example. For example, the red pixel PB, the green pixel PG, and the blue pixel PB may be provided with the respective light-emitting elements that emit ultraviolet rays, the red pixel PR may be provided with the red wavelength conversion layer 206R containing the QDs 112R that serve as the QDs 112 and emit a red light, the green pixel PG may be provided with the green wavelength conversion layer 206G containing the QDs 112G that serve as the QDs 112 and emit a green light, and the blue pixel PB may be provided with a blue wavelength conversion layer containing QDs that serve as the QDs 112 and emit a blue light.

In any case, this embodiment can omit a solvent when the wavelength conversion layers are formed of the cured resin 114 in which the QDs 112 are thoroughly dispersed. Such a feature can reduce the coffee ring effect occurring in evaporation of the solvent. Hence, the in-plane variation observed in the light-emitting layer 22 is successfully reduced (relieved). Moreover, as described above, even if the QD-containing film is the wavelength conversion layer of the wavelength conversion sheet 206, this embodiment can reduce the in-plane variation observed in the wavelength conversion layer when the solvent evaporates. Such a feature makes it possible to planarize the surface of the wavelength conversion layer. As a result, the display device 202 is expected to improve adhesion between the wavelength conversion sheet 206 and an upper layer (e.g., the CF sheet 207 in FIG. 2) of the wavelength conversion sheet 206. Others

Although not shown, the QD-containing film may be used for, for example, a solar cell. In this case, as well, this embodiment can omit a solvent when the QD-containing film is formed of the cured resin 114 in which the QDs 112 are thoroughly dispersed. Such a feature can reduce the coffee ring effect occurring in evaporation of the solvent. Hence, the same curing as that described above can be achieved.

### Second Embodiment

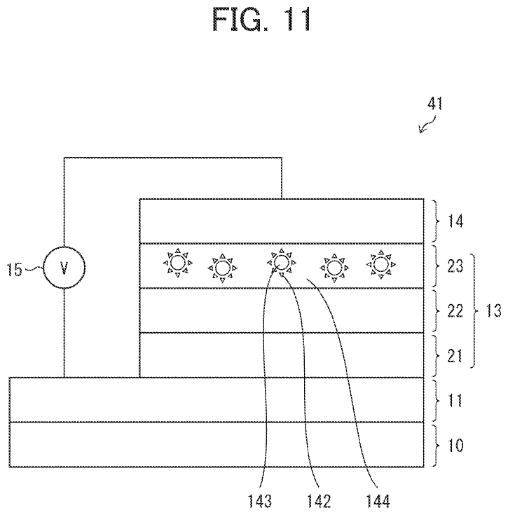

Another embodiment of the present disclosure will be described below, with reference to FIGS. 11 to 13. Note that this embodiment describes differences from the first embodiment. For convenience in description, like reference signs designate members having identical functions between this embodiment and the first embodiment. These members will not be elaborated upon repeatedly.

As described in the first embodiment, the nanoparticles 102 may be inorganic nanoparticles capable of transporting carriers.

Exemplified below is a case where the nanoparticles 102 are inorganic nanoparticles capable of transporting carriers, and where the nanoparticle-containing film is the second carrier transport layer 23 of a light-emitting element.

### Light-Emitting Element

FIG. 11 is a cross-sectional view of a schematic configuration of a light-emitting element 41 according to this embodiment.

As illustrated in FIG. 11, similar to the light-emitting element 1, the light-emitting element 41 according to this embodiment includes: the substrate 10; the first electrode 11; the first carrier transport layer 21; the light-emitting layer 22; the second carrier transport layer 23; and the second electrode 14, all of which are stacked on top of another in the stated order from below.

In the light-emitting element 41 illustrated in FIG. 11, at least the second carrier transport layer 23 is a nanoparticle-containing film made of the nanoparticle composition 101.

The second carrier transport layer 23 contains: inorganic nanoparticles 142 serving as the nanoparticles 102 and capable of transporting carriers; ligands 143 serving as the ligands 103; a cured resin 144 (a curable polymer) obtained when the curable monomer 104 is cured. Note that, in FIG. 11, the inorganic nanoparticles 142 and the ligands 143 are illustrated larger in size and smaller in number.

Note that the light-emitting layer 22 of the light-emitting element 41 may be the same as, or different from, the light-emitting layer 22 of the light-emitting element 1. If the light-emitting element 41 is a QLED, the light-emitting layer 22 of the light-emitting element 41 is desirably a QD-containing film made of the QD composition 111 as described in the first embodiment. However, the light-emitting layer 22 may be a QD-containing film not containing the cured resin 114. Furthermore, the light-emitting element 41 may be either an IOLED or an OLED.

The inorganic nanoparticles 142 are the inorganic nanoparticles exemplified as the nanoparticles 102 in the first embodiment and capable of transporting carriers. The ligands 143 are the ligands exemplified as the ligands 103. Hence, the description of the ligands 103 in the first embodiment can be used as it is for the description of the ligands 143.

The cured resin 144 is, as described above, a cured product obtained when the curable monomer 104 is cured. Because the curable monomer 104 is an aromatic monomer, the cured resin 144 contains an aromatic polymer containing aromatic rings. Note that the curable monomer 104 has been previously described in the first embodiment. The description of the cured resin 114 in the first embodiment can be used as it is for the description of the cured resin 144.

The cured resin 144 functions as a binder resin for bonding together the inorganic nanoparticles 142 coordinated with the ligands 143. The inorganic nanoparticles 142 coordinated with the ligands 143 disperse in the cured resin 144.

As can be seen, even if the nanoparticle-containing film is the second carrier transport layer 23, a proportion of the sum of the compounds having aromatic rings and contained in the second carrier transport layer 23 is preferably 50 wt % or more. More preferably, all the compounds have aromatic rings except for the inorganic nanoparticles 142.

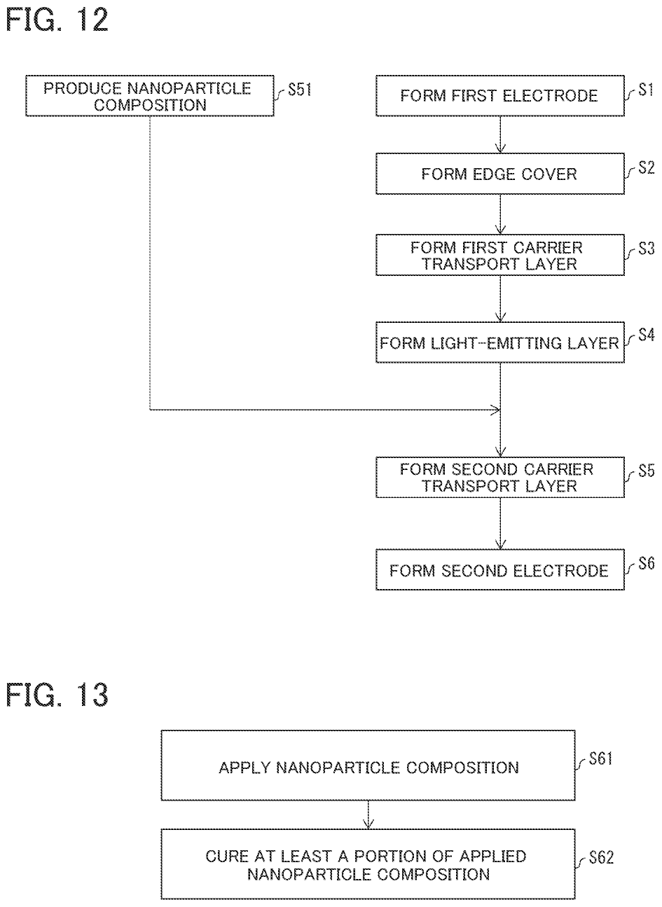

Methods for Producing Light-Emitting Element 41 and Nanoparticle-Containing Film Next, a method for producing the nanoparticle-containing film containing the inorganic nanoparticles 142 will be described, citing, as an example, a method for producing the second carrier transport layer 23 formed in the process of producing the light-emitting element 41. FIG. 12 is a flowchart showing an example of a method for producing the light-emitting element 41 according to this embodiment. Note that FIG. 12 shows, as an example, a method for producing the light-emitting element 41 illustrated in FIG. 11. Furthermore, described below will be a case where the first electrode 11 has an edge covered with a not-shown edge cover.

As illustrated in FIG. 12, in the method for producing the light-emitting element 41 according to this embodiment, first, as an example, the first electrode 11 is formed on the substrate 10 as seen in the method for producing the light-emitting element 1 illustrated in FIG. 2 (Step S1: the first electrode forming step). Next, a not-shown edge cover is formed to cover an edge of the first electrode 11 (Step S2: the edge cover forming step). Next, the first carrier transport layer 21 is formed (Step S3: the first carrier transport layer forming step). Next, the light-emitting layer 22 is formed (Step S4: the light-emitting layer forming step). Although not shown, when the QD-containing film made of the QD composition 111 is formed as the light-emitting layer 22 as described in the first embodiment, the QD composition producing step (Step S11: the nanoparticle composition producing step) is carried out before Step S4. After Step S4 (the light-emitting layer forming step), in this embodiment as well, the second carrier transport layer forming step is carried out as Step S5 to form the second carrier transport layer 23. Note that, in this embodiment, a nanoparticle composition producing step (Step S51) is carried out before Step S5. The nanoparticle composition producing step involves producing (preparing), as the nanoparticle composition 101, a nanoparticle composition containing: the inorganic nanoparticles 142; the ligands 143; the curable monomer 104; and, as necessary, the polymerization initiator 105. Then, after Steps S4 and S51, the nanoparticle composition is used to form the second carrier transport layer 23 serving as a nanoparticle-containing film containing the inorganic nanoparticles 142. After that, in this embodiment as well, the second electrode 14 is formed (Step S6: the second electrode forming step).

Step S51 described above is the same as Step S11 described in the first embodiment except that, for example, the exchange of the ligands for the QDs 112 carried out at Step S11 described in the first embodiment is replaced with provision of ligands to the inorganic nanoparticles 142.

In this embodiment, for example, aromatic ligands are added to a nanoparticle-dispersed solution containing the inorganic nanoparticles 142 and an organic solvent, so that the inorganic nanoparticles 142 are coordinated with the aromatic ligands. After that, similar to Step S23, impurities such as excess aromatic ligands not coordinated to the inorganic nanoparticles 142 are removed for purification. Then, the inorganic nanoparticles 142 modified with the aromatic ligands are isolated in the form of powder. Then, as seen at Step S24, the powder of the inorganic nanoparticles 142 modified with the aromatic ligands (i.e., the inorganic nanoparticles 142 modified with the ligands 143) is mixed with the curable monomer 104 containing an aromatic monomer. Note that, in this embodiment as well, the polymerization initiator 105 may be mixed here as necessary.

Furthermore, as described at Step S24 with reference to FIGS. 5 and 6, the mixing desirably involves heating and mixing together the powder of the nanoparticles 102 modified with the aromatic ligands (in this embodiment, the inorganic nanoparticles 142 modified with the aromatic ligands) and the curable monomer 104 containing a photo-curable monomer. Moreover, the mixing is desirably carried out by ultrasonic treatment while heat is applied. Note that how to add and mix the polymerization initiator 105 has been previously described in the first embodiment.

As a result, as the nanoparticle composition 101, a nanoparticle composition can be produced to contain: the inorganic nanoparticles 142; the ligands 143 containing the aromatic ligands; the curable monomer 104; and, as necessary, the polymerization initiator 105.

Note that the above description exemplifies a case where Step S51 described above involves providing ligands to the inorganic nanoparticles 142. However, this embodiment shall not be limited to this example.

For example, if synthesized or commercially available inorganic nanoparticles 142 are coordinated with non-aromatic ligands serving as original ligands, ligand exchange may be carried out as seen in the first embodiment.

Furthermore, in this embodiment as well, if the original ligands are aromatic ligands, the ligand exchange does not have to be carried out.

In any case, in this embodiment as well, a sum of contents of the inorganic nanoparticles 142 serving as the nanoparticles 102 and the aromatic ligands in the nanoparticle composition is desirably within a range of 0.01 wt % or more and 10 wt % or less as described in the first embodiment. Furthermore, in order to express a sufficient x-x stacking, a content of the aromatic ligands in the ligands 143 is preferably 10 wt % or more, and more preferably, 50 wt % or more. Most preferably, all of the ligands 143 are the aromatic ligands.

FIG. 13 is a flowchart showing an example of Step S5 (the second carrier transport layer forming step).

As show in FIG. 13, at Step S5, first, the nanoparticle composition produced at Step S51 is applied to an underlayer (e.g., the light-emitting layer 22 in FIG. 11) serving as a support of the second carrier transport layer 23 (Step S61: an applying step).

Next, at least a portion of the curable monomer 104 of the nanoparticle composition applied at Step S61 is cured (Step S62: a curing step). Step S62 forms the second carrier transport layer 23 formed of the cured resin 144 in which the inorganic nanoparticles 142 modified with aromatic ligands are thoroughly dispersed. Here, the nanoparticle composition is applied by application techniques such as, for example, spin coating. Note that, the second carrier transport layer 23 is desirably patterned by photolithography, as seen in the case of the light-emitting layer 22 in the light-emitting element 1.

The nanoparticle composition containing the inorganic nanoparticles 142 serving as the nanoparticles 102 does not contain a solvent. Without a solvent, the second carrier transport layer 23 is successfully formed of the cured resin 144 in which the inorganic nanoparticles 142 are thoroughly dispersed. Such a feature can reduce (relieve) the coffee ring effect occurring in evaporation of the solvent, and in-plane variation observed in the second carrier transport layer 23. Note that, in this embodiment as well, the advantageous effects to be obtained can be greater with higher definition of a pattern of a formed nanoparticle film. Moreover, as described above, this embodiment can reduce the in-plane variation observed in the second carrier transport layer 23 when the solvent evaporates. Such a feature makes it possible to further planarize the surface of the second carrier transport layer 23. As a result, this embodiment is expected to improve adhesion between the second carrier transport layer 23 and an upper layer (e.g., the second electrode 14 in FIG. 11) of the second carrier transport layer 23, and to increase current injection efficiency.

Furthermore, this embodiment is expected to further increase carrier injection efficiency because not only the light-emitting layer 22 but also the second carrier transport layer 23 is separately coated.

This embodiment can be ideally applied to formation of, for example, an electron transport layer using ZnO nanoparticles. However, this embodiment shall not be limited to such an example. As described in the first embodiment, the nanoparticles 102 may be, for example, inorganic nanoparticles capable of transporting holes. Hence, the nanoparticle-containing film according to this embodiment may be a hole transport layer.

Furthermore, this embodiment exemplifies a case where at least the second carrier transport layer 23 is a nanoparticle-containing film. However, this embodiment shall not be limited to such an example. The first carrier transport layer 21 may be a nanoparticle-containing film made of the nanoparticle composition 101. Moreover, each of the first carrier transport layer 21 and the second carrier transport layer 23 may be a nanoparticle-containing film made of the nanoparticle composition 101. In addition, as described above, the light-emitting layer 22 may also be a nanoparticle-containing film made of the nanoparticle composition 101. Furthermore, the display device 2 may include the light-emitting element 41 instead of the light-emitting element 1.

### Third Embodiment

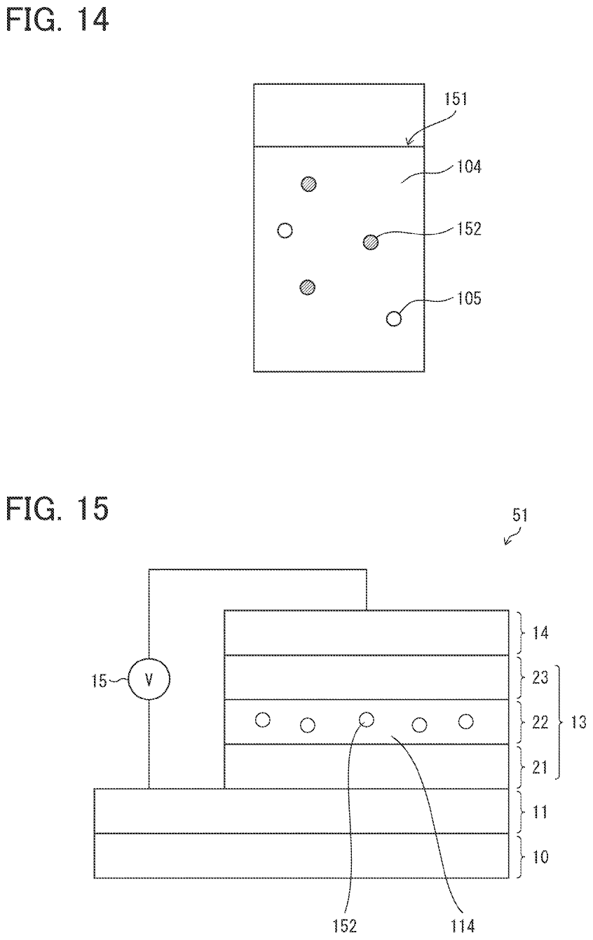

Still another embodiment of the present disclosure will be described below, with reference to FIGS. 14 and 15. Note that this embodiment describes differences mainly from the first embodiment. For convenience in description, like reference signs designate members having identical functions between this embodiment and the first embodiment. These members will not be elaborated upon repeatedly.

The first embodiment exemplifies a case where the nanoparticle composition 101 is, for example, the QD composition 111, where the QD composition 111 contains, for example, the QDs 112 serving as the nanoparticles 102, and where the QDs 112 are, for example, inorganic-based semiconductor quantum dots.

However, the nanoparticles 102 may be carbon-based quantum dots containing aromatic rings. Hence, a nanoparticle composition according to the present disclosure may be the nanoparticle composition 101 in which: the nanoparticles 102 contain carbon-based quantum dots containing aromatic rings; the ligands 103 contain aromatic ligands containing aromatic rings; and the curable monomer 104 contains an aromatic monomer. In this case, the QDs 112 serving as the nanoparticles 102 are the carbon-based quantum dots containing aromatic rings, and the carbon-based quantum dots are contained in a compound having aromatic rings. Here, the compound is contained in the QD composition 111 and in a QD-containing film made of the QD composition 111. Note that, as the QDs 112, the carbon-based quantum dots containing aromatic rings and inorganic-based semiconductor quantum dots may be used in combination.

However, if the nanoparticles 102 are carbon-based quantum dots containing aromatic rings, the ligands 103 are not necessarily required.

As described above, the nanoparticle composition according to the present disclosure may contain, out of nanoparticles and ligands, at least the nanoparticles, and a curable monomer. At least the nanoparticles or the ligands contained in the nanoparticle composition may contain aromatic rings. The curable monomer may contain an aromatic monomer.

Hence, exemplified below is a case where the nanoparticle composition according to the present disclosure contains the nanoparticles alone out of the nanoparticles and the ligands; that is, exemplified below is a case where the nanoparticle composition according to the present disclosure contains nanoparticles and a curable monomer, where the nanoparticles contain aromatic rings, and where the curable monomer is a nanoparticle composition containing an aromatic monomer. More specifically, exemplified below is a case where the nanoparticles are QDs, and where the nanoparticle composition is a QD composition.

### QD Composition

FIG. 14 is a cross-sectional view schematically illustrating an example of a nanoparticle composition 151 according to this embodiment.

The QD composition 151 illustrated in FIG. 14 contains: carbon-based QDs 152 that are carbon-based quantum dots containing aromatic rings; the curable monomer 104; and, as necessary, the polymerization initiator 105. Note that FIG. 14 schematically illustrates the polymerization initiator 105. Furthermore, in FIG. 14, the carbon-based QDs 152 and the polymerization initiator 105 are illustrated larger in size and smaller in number of particles.

The carbon-based QDs 152 are organic-based quantum dots having a nano-size particle diameter and containing aromatic rings. Examples of the carbon-based QDs 152 include graphene quantum dots and carbon quantum dots. In particular, the carbon-based quantum dots have attracted attention in recent years as low-cost and non-cadmium (Cd)/non-lead (Pb) colloidal semiconductor quantum dots capable of emitting visible light to near-infrared light.

Note that the term “non-Cd” means Cd-free, and the term “non-Pb” means Pb-free.

### Light-Emitting Element

FIG. 15 is a cross-sectional view of a schematic configuration of a light-emitting element 51 according to this embodiment.

As illustrated in FIG. 15, similar to the light-emitting element 1, the light-emitting element 51 according to this embodiment includes: the substrate 10; the first electrode 11; the first carrier transport layer 21; the light-emitting layer 22; the second carrier transport layer 23; and the second electrode 14, all of which are stacked on top of another in the stated order from below.

In the light-emitting element 51 illustrated in FIG. 15, at least the light-emitting layer 22 is a nanoparticle-containing film made of the nanoparticle composition 151.

The light-emitting layer 22 contains: the carbon-based QDs 152 as nanoparticles; and the cured resin 114 (a curable polymer) obtained when the curable monomer 104 is cured. Note that, in FIG. 15, the carbon-based QDs 152 are illustrated larger in size and smaller in number.

As can be seen, when the light-emitting layer 22 contains the carbon-based QDs 152 and the cured resin 114, a proportion of the sum of compounds having aromatic rings and contained in the light-emitting layer 22 is preferably 50 wt % or more.

Note that, in this embodiment, the compounds having aromatic rings and contained in the light-emitting layer 22 are derived from compounds having aromatic rings and contained in the QD composition 151. That is, the compounds having aromatic rings and contained in the light-emitting layer 22 are, for example: the carbon-based QDs 152; and a cured resin having aromatic rings and contained in the cured resin 114. Depending on a reaction state, the compounds contain: an aromatic monomer contained in the unreacted curable monomer 104; an aromatic oligomer; and a polymerization initiator having aromatic rings and contained in the unreacted polymerization initiator 105.

In this embodiment, the carbon-based QDs 152 contain aromatic rings. Hence, more desirably, the light-emitting layer 22 is made only of a compound having aromatic rings.

Methods for Producing Light-Emitting Element 51 and QD-Containing Film

A method for producing the light-emitting element 51 according to this embodiment is the same as the method for producing the light-emitting element 1 described in the first embodiment except that the QD composition 151 is used as the nanoparticle composition. Hence, the light-emitting element 51 is produced according to the flowchart shown in FIG. 3 as the light-emitting element 1 is.

The QD composition producing step (Step S11) according to this embodiment eliminates the need for exchanging and providing ligands, unlike the first and second embodiments.

Hence, the QD composition producing step (Step S11) only needs to include a mixing step of mixing together the carbon-based QDs 152, the curable monomer 104 containing an aromatic monomer, and, as necessary, the polymerization initiator 105. Note that, the QD composition producing step may involve purifying and isolating the carbon-based QDs 152 as necessary.

Note that, as can be seen, even when the carbon-based QDs 152 are used as the QDs, the mixing desirably involves heating and mixing together the QDs (in this embodiment, the carbon-based QDs 152) and the curable monomer 104 containing a photo-curable monomer, as seen in the first embodiment. Moreover, the mixing is desirably carried out by ultrasonic treatment while heat is applied. How to add and mix the polymerization initiator 105 has been previously described in the first embodiment.

As a result, as the nanoparticle composition 151, a nanoparticle composition can be produced to contain: the carbon-based QDs 152; the curable monomer 104; and, as necessary, the polymerization initiator 105.

Step S4 (the light-emitting layer forming step) is the same as that of the first embodiment except that the QD composition 151 is used in stead of the QD composition 111. Hence, in this embodiment as well, the light-emitting layer 22 is produced according to the flowchart shown in FIG. 7 as the light-emitting element 1 is.

That is, in this embodiment, first, the QD composition 151 produced at Step S11 is applied to the underlayer (e.g., the first carrier transport layer 21 in FIG. 15) serving as the support of the light-emitting layer 22 (Step S41: the applying step).

Next, at least a portion of the curable monomer 104 of the QD composition 151 applied at Step S41 is cured (Step S42: the curing step). Step S42 forms the light-emitting layer 22 formed of the cured resin 114 in which the carbon-based QDs 152 are thoroughly dispersed.

As described above, the carbon-based QDs 152 contain aromatic rings. Hence, according to this embodiment, a x-x stacking between the aromatic rings of the carbon-based QDs 152 and the aromatic rings of the curable monomer 104 successfully keep the carbon-based QDs 152 from agglomerating together. Thus, according to this embodiment, this noncovalent-bonding π-π stacking allows the carbon-based QDs 152 to directly disperse into the curable monomer 104 without a solvent.

The QD composition 151 used in this embodiment does not contain a solvent. Without a solvent, the light-emitting layer 22 is successfully formed of the cured resin 114 in which the carbon-based QDs 152 are thoroughly dispersed. In this embodiment as well, such a feature can reduce (relieve) the coffee ring effect occurring in evaporation of the solvent, and in-plane variation observed in the light-emitting layer 22. Moreover, as described above, this embodiment can reduce the in-plane variation observed in the light-emitting layer 22 when the solvent evaporates. Such a feature makes it possible to further planarize the surface of the light emitting layer 22. As a result, this embodiment is expected to improve adhesion between the light-emitting layer 22 and an upper layer (e.g., the second carrier transport layer 23 in FIG. 15) of the light-emitting layer 22, and to increase current injection efficiency.

Furthermore, in this embodiment, the aromatic rings of the carbon-based QDs 152 can be used, and, as described above, the ligands can be omitted. Such a feature can eliminate the need for the ligands in moving the carriers, thereby successfully improving mobility of the carriers and bringing the carbon-based QDs 152 together in proximity. As a result, the light-emitting element 51 can improve light emission efficiency. Moreover, because no ligands are used, neither ligand degradation nor ligand desorption is observed. As a result, the QD-containing film and the light-emitting element 51 are successfully provided with great reliability.

Note that this embodiment exemplifies a case where the QD-containing film made of the QD composition 151 is the light-emitting layer of the light-emitting element. However, this embodiment shall not be limited to this example. The QD-containing film may be a wavelength conversion layer of a wavelength conversion member as seen in the first embodiment. Furthermore, the display device may include the light-emitting element, and may also include the wavelength conversion member as a photoelectric converting unit.

Although not shown, the QD-containing film may be used for, for example, a solar cell.

Although not shown, in the light-emitting element 51, at least one of the first carrier transport layer 21 or the second carrier transport layer 23 may be a nanoparticle-containing film containing: the inorganic nanoparticles 142 capable of transporting carriers; the ligands 143; and the cured resin 144, as described in the second embodiment.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. A nanoparticle composition, comprising:
out of nanoparticles and ligands, at least the nanoparticles; and a curable monomer,
wherein, at least the nanoparticles or the ligands contained in the nanoparticle composition contain aromatic rings,
the curable monomer contains an aromatic monomer,
the aromatic monomer is a (meth) acrylate-based monomer having at least one (meth) acryloyl group,
the aromatic monomer is a diacrylate derivative,
the diacrylate derivative is a compound represented by a structural formula (1) below, in the structural formula (1), each of R¹ and R² independently represents a hydrogen atom or a methyl group, and a relationship of n+m=4 holds, and
the diacrylate derivative is a compound in which each of the R¹ and the R² in the structural formula (1) is a hydrogen atom.

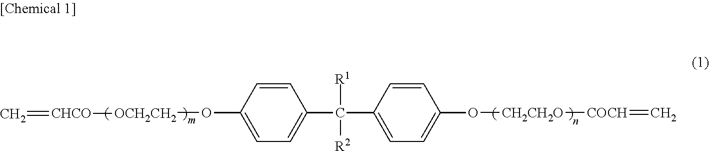

2-7. (canceled)

8. The nanoparticle composition according to claim 1, further comprising
a photopolymerization initiator.

9. The nanoparticle composition according to claim 8,
wherein the photopolymerization initiator contains aromatic rings.

10. The nanoparticle composition according to claim 8,
wherein the photopolymerization initiator is an acylphosphine-oxide-based photopolymerization initiator.

11. The nanoparticle composition according to claim 10,
wherein the acylphosphine-oxide-based photopolymerization initiator is a compound represented by a structural formula (2) below, 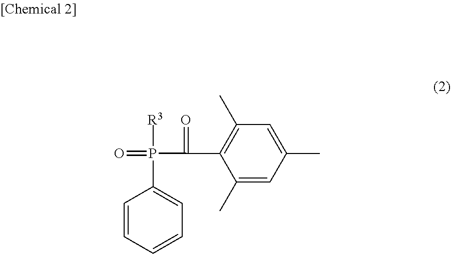
wherein R³ represents a group 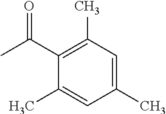
or a group

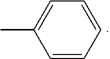

12. The nanoparticle composition according to claim 10, wherein the acylphosphine-oxide-based photopolymerization initiator is bis (2,4,6-trimethylbenzoyl) phenylphosphine oxide.

13. (canceled)

14. The nanoparticle composition according to claim 1, comprising
both the nanoparticles and the ligands,
wherein the ligands contain aromatic ligands containing aromatic rings.

15-36. (canceled)

37. A nanoparticle composition, comprising:
out of nanoparticles and ligands, at least the nanoparticles; and a curable monomer,
wherein, at least the nanoparticles or the ligands contained in the nanoparticle composition contain aromatic rings,
the curable monomer contains an aromatic monomer, and
the nanoparticles contain carbon-based quantum dots containing aromatic rings.

38. The nanoparticle composition according to claim 37,
wherein the aromatic monomer is a (meth) acrylate-based monomer having at least one (meth) acryloyl group.

39. The nanoparticle composition according to claim 38,
wherein the aromatic monomer is a diacrylate derivative.

40. The nanoparticle composition according to claim 39,
wherein the diacrylate derivative is a compound represented by a structural formula (1) below, 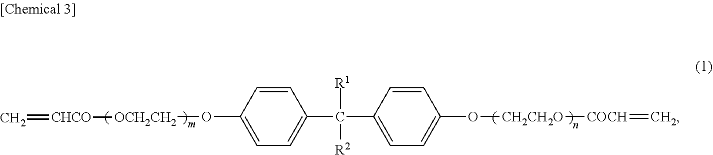
and
in the structural formula (1), each of R¹ and R² independently represents a hydrogen atom or a methyl group, and a relationship of n+m=4 holds.

41. The nanoparticle composition according to claim 40,
wherein the diacrylate derivative is a compound in which each of the R¹ and the R² in the structural formula (1) is a hydrogen atom.

42. The nanoparticle composition according to claim 37, further comprising
a photopolymerization initiator.

43. The nanoparticle composition according to claim 42,
wherein the photopolymerization initiator contains aromatic rings.

44. The nanoparticle composition according to claim 42,
wherein the photopolymerization initiator is an acylphosphine-oxide-based photopolymerization initiator.

45. The nanoparticle composition according to claim 44,
wherein the acylphosphine-oxide-based photopolymerization initiator is a compound represented by a structural formula (2) below, 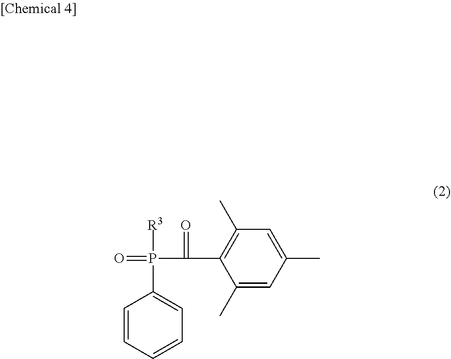
wherein R³ represents a group 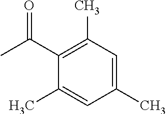
or a group

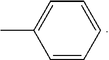

46. The nanoparticle composition according to claim 37, comprising
both the nanoparticles and the ligands,
wherein the ligands contain aromatic ligands containing aromatic rings.

47. The nanoparticle composition according to claim 37, comprising
the nanoparticles alone out of the nanoparticles and the ligands.

48. A wavelength conversion member comprising, a nanoparticle-containing film as a wavelength conversion layer, wherein
the nanoparticle-containing film comprising: out of nanoparticles and ligands, the nanoparticles; and a cured resin,
at least the nanoparticles or the ligands contained in the nanoparticle-containing film contain aromatic rings, and
the cured resin contains an aromatic polymer.

49. A display device comprising the wavelength conversion member according to claim 48.
